(19) United States
(12) Patent Application Publication
(10) Pub. No.: US 2008/0100213 A1
(43) Pub. Date: May 1, 2008

(54) LUMINESCENT DEVICE

(75) Inventors: Toshihiro Iwakuma, Sodegaura-shi (JP); Toshinori Matsushima, Nomi (JP); Chihaya Adachi, Fukuoka-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: Idemitsu Kosan Co., Ltd., Chiyoda-ku (JP); KYUSHU UNIVERSITY, Fukuoka-shi (JP)

(21) Appl. No.: 11/846,233

(22) Filed: Aug. 28, 2007

(30) Foreign Application Priority Data
Oct. 31, 2006 (JP) 2006-295803

(51) Int. Cl. H01J 1/62

(52) U.S. Cl. 313/506

(57) ABSTRACT

A luminescent device including a plurality of layers including a layer containing a luminescent substance between a first electrode and a second electrode, at least one layer of the plurality of layers containing a thiophene derivative represented by the following formula (1) and a substance exhibiting electron acceptability for the thiophene derivative.

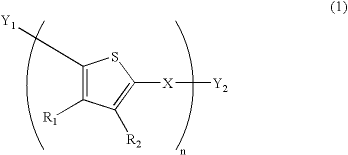

### TECHNICAL FIELD

The invention relates to a luminescent device. More particularly, the invention relates to an organic electroluminescent device in which layers comprising a specific thiophene derivative and a substance exhibiting electron acceptability for the thiophene derivative are formed.

### BACKGROUND

An organic electroluminescent device (hereinafter the term “electroluminescent” is often abbreviated as “EL”) is a self-emission device utilizing the principle that a fluorescent compound emits light by the recombination energy of holes injected from an anode and electrons injected from a cathode when an electric field is impressed.

In recent years, demand for reduction of power consumption has been particularly increased in the field of a display which is incorporated into various information processing devices. To achieve this aim, attempts have been made to develop a luminescent device which can be driven at a low voltage.

For example, Patent document 1 discloses a technology for driving a luminescent device at a low voltage by using as an anode a metal oxide having a high work function such as a molybdenum oxide.

Patent document 2 discloses an organic semiconductor device in which a floating conductive thin film layer is provided between two functional organic thin film layers, and the conductive thin film layer ohmically contacts the functional thin film layers.

In addition, Patent documents 3 to 12 describe technologies for increasing the efficiency and decreasing the driving voltage of the device by reviewing the layer structure between the electrodes, as well as the material constituting the layers. Also, non-patent documents 1 to 8 describe related technologies.

[Patent document 1] JP-A-09-63771

[Patent document 2] JP-A-2003-264085

[Patent document 3] JP-A-2004-228081

[Patent document 4] JP-A-2005-32618

[Patent document 5] JP-A-2005-123095

[Patent document 6] JP-A-2005-166637

[Patent document 7] JP-A-2005-166641

[Patent document 8] JP-A-2006-186333

[Patent document 9] JP-A-2006-186335

[Patent document 10] JP-A-2006-179869

[Patent document 11] Japanese Patent No. 3748110

[Patent document 12] Japanese Patent No. 2826381

[Non-patent document 1] T. Oyamada et al., Appl. Phys. Lett. 86, 033503 (2005)

[Non-patent document 2] X. Zhou et al., Appl. Phys. Lett. 78, 410-412 (2001)

[Non-patent document 3] G. He et al., Appl. Phys. Lett. 85, 3911-3913 (2004)

[Non-patent document 4] J. Huang et al., Appl. Phys. Lett. 80, 139-141 (2002)

[Non-patent document 5] M. Pfeiffer et al., Adv. Matter. 14, 1633-1636 (2002)

[Non-patent document 6] X. Zhou et al., Adv. Fun. Matter. 11, 310-314 (2001)

[Non-patent document 7] J. Blochwitz et al., Appl. Phys. Lett. 73, 729-731 (1998)

[Non-patent document 8] M. Pfeiffer et al., Appl. Phys. Lett. 73, 3202-3204 (1998)

An object of the invention is to provide a luminescent device which can be driven at a low voltage.

### SUMMARY OF INVENTION

The inventors have found that, in an organic EL device, the driving voltage of the device can be significantly decreased by forming a layer containing a specific thiophene compound to which an electron-acceptable substance is added. The invention has been made based on this finding.

According to the invention, the following luminescent device can be provided.
1. A luminescent device comprising a plurality of layers including a layer containing a luminescent substance between a first electrode and a second electrode, at least one layer of the plurality of layers containing, comprises essentially of, or consists of a thiophene derivative represented by the following formula (1) and a substance exhibiting electron acceptability for the thiophene derivative: 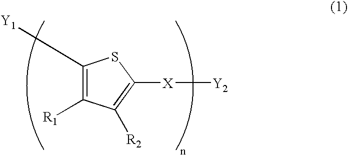
wherein R₁ and R₂ are independently a hydrogen atom, a halogen atom, a cyano group, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms; R₁ and R₂ may be bonded to each other to form a ring; X is a single bond or a substituted or unsubstituted divalent group; Y₁ and Y₂ are independently a hydrogen atom or a substituted or unsubstituted monovalent group; n is an integer of 1 to 20; and when n is 2 or more, R₁s, R₂s and Xs may be the same or different.
2. The luminescent device according to 1, wherein in the formula (1), X is a single bond or a substituted or unsubstituted arylene group having 6 to 20 carbon atoms, and Y₁ and Y₂ are a group selected from the group consisting of a hydrogen atom, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms.
3. The luminescent device according to 1, wherein the thiophene derivative is represented by the following formula (2): 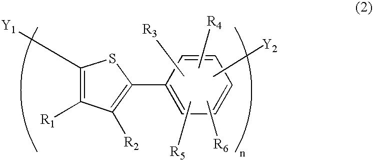
wherein R₁ to R₆ are independently a hydrogen atom, a halogen atom, a cyano group, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms; adjacent substituents may be bonded to each other to form a ring; Y₁ and Y₂ are independently a hydrogen atom or a substituted or unsubstituted monovalent group; n is an integer of 1 to 20; and when n is 2 or more, R₁s to R₆s may be the same or different.
4. The luminescent device according to 1, wherein the thiophene derivative is represented by the following formula (3): 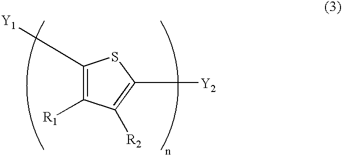
wherein R₁ to R₂ are independently a hydrogen atom, a halogen atom, a cyano group, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms; adjacent substituents may be bonded to each other to form a ring; Y₁ and Y₂ are independently a hydrogen atom or a substituted or unsubstituted monovalent group; n is an integer of 1 to 20; and when n is 2 or more, R₁s and R₂s may be the same or different.
5. The luminescent device according to 3 or 4, wherein in the formula (2) or (3), Y₁ and Y₂ are independently a hydrogen atom, an alkyl group having 1 to 20 carbon atoms, a substituted or unsubstituted aryl group having 6 to 40 ring carbon atoms, and a substituted or unsubstituted heterocyclic residue having 2 to 40 ring carbon atoms.
6. The luminescent device according to 1, wherein the thiophene derivative has a bithiophene structure, a terthiophene structure, or a quarterthiophene structure.
7. The luminescent device according to one of 1 to 6, wherein the layer containing the thiophene derivative and the substance exhibiting electron acceptability is present in a hole-transporting region.
8. The luminescent device according to one of 1 to 7, wherein the substance exhibiting electron acceptability is an electron-acceptable compound containing a cyano group.
9. The luminescent device according to one of 1 to 7, wherein the substance exhibiting electron acceptability is a compound represented by the following formula (6): 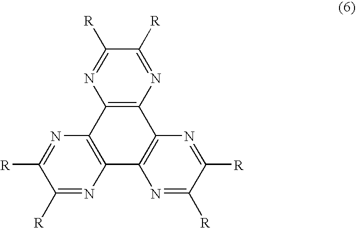
wherein Rs are independently a halogen atom, a cyano group, a nitro group, an alkyl group, a trifluoromethyl group, an aryloxycarbonyl group, an alkoxycarbonyl group, a dialkylcarbamoyl group, a diarylcarbamoyl group, or a carboxyl group.
10. The luminescent device according to one of 1 to 7, wherein the substance exhibiting electron acceptability is one or a plurality of metal oxides.
11. The luminescent device according to 10, wherein the metal oxide is an oxide of a transition metal belonging to the groups 4 to 12 of the periodic table.
12. The luminescent device according to 10, wherein the metal oxide is an oxide of a transition metal belonging to the groups 4 to 8 of the periodic table.
13. The luminescent device according to 10, wherein the metal oxide is selected from the group consisting of a molybdenum oxide (MoOx), a vanadium oxide (VOx), a ruthenium oxide (RuOx), a tungsten oxide (WOx), a rhenium oxide (ReOx), a titanium oxide (TiOx), a chromium oxide (CrOx), a zirconium oxide (ZrOx), a hafnium oxide (HfOx), and tantalum oxide (TaOx) (x in the composition formulas is a number of 2 to 3).

The invention provides a luminescent device which can be driven at a low voltage.

### BRIEF DESCRIPTION OF THE DRAWINGS

FIG. 1 is a schematic cross-sectional view showing one embodiment of the luminescent device of the invention.

FIG. 2 is a view showing the current density-voltage characteristics of the organic EL device fabricated in Examples or the like.

FIG. 3 is a view showing the external quantum efficiency-current density characteristics of the organic EL device fabricated in Examples or the like.

FIG. 4 is a view showing the luminous efficiency-current density characteristics of the organic EL device fabricated in Examples or the like.

FIG. 5 is a view showing the luminous efficiency-voltage characteristics of the organic EL device fabricated in Examples or the like.

### BEST MODE FOR CARRYING OUT THE INVENTION

A luminescent device according to the invention is described below in detail.

The luminescent device of the invention has a plurality of layers including a layer containing a luminescent substance between the first electrode and the second electrode. One example of the device will be explained referring to the drawings.

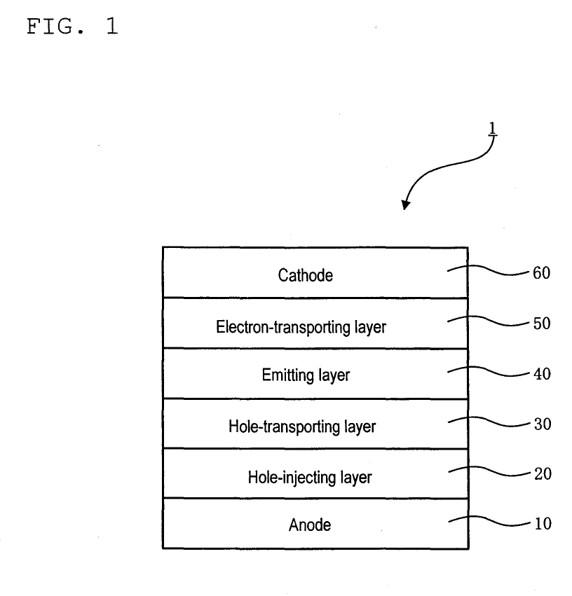

FIG. 1 is a schematic cross-sectional view showing one embodiment of the luminescent device of the invention.

In the luminescent device 1, an anode 10 (first electrode), a hole-injecting layer 20, a hole-transporting layer 30, an emitting layer 40, an electron-transporting layer 50, and a cathode 60 (second electrode) are stacked on a substrate (not shown) in this order.

In this device, the emitting layer 40 is a layer which contains a luminescent substance. The hole-injecting layer 20, hole-transporting layer 30, emitting layer 40, and electron-transporting layer 50 correspond to the plurality of layers provided between the first electrode and the second electrode.

In the invention, of the plurality of layers, at least one layer contains a thiophene derivative represented by the following formula (1) and a substance exhibiting electron acceptability for the thiophene derivative. 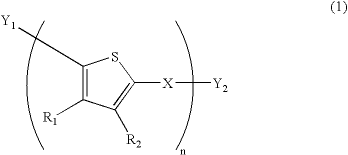
wherein R₁ and R₂ are independently a hydrogen atom, a halogen atom, a cyano group, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms; R₁ and R₂ may be bonded to each other to form a ring; X is a single bond or a substituted or unsubstituted divalent group; Y₁ and Y₂ are a substituted or unsubstituted monovalent group; n is an integer of 1 to 20; and when n is 2 or more, R₁s, R₂s and Xs may be the same or different.

The driving voltage of the luminescent device can be significantly lowered by adding to the same layer the thiophene derivative and the substance exhibiting electron acceptability for the thiophene derivative.

In the luminescent device of the invention, it is preferred that at least one layer of the plurality of layers mentioned above be a layer which serves to generate or transport holes. These layers are preferably provided in a hole-transporting region, i.e., a region between the anode and the emitting layer. In the invention, it is preferred that these layers contain the above-mentioned thiophene derivative and the electron-acceptable substance.

In the formula (1), R₁ and R₂ are independently a hydrogen atom, a halogen atom, a cyano group, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms.

As the halogen atom, fluorine, chlorine, bromine, iodine or the like can be given.

Examples of the alkyl groups include methyl, ethyl, propyl, isopropyl, n-butyl, s-butyl, isobutyl, t-butyl, n-pentyl, n-hexyl, n-heptyl, n-octyl, n-nonyl, n-decyl, n-undecyl, n-dodecyl, n-tridecyl, n-tetradecyl, n-pentadecyl, n-hexadecyl, n-heptadecyl, n-octadecyl, neopentyl, 1-methylpentyl, 2-methylpentyl, 1-pentylhexyl, 1-butylpentyl, 1-heptyloctyl, 3-methylpentyl, hydroxymethyl, 1-hydroxyethyl, 2-hydroxyethyl, 2-hydroxyisobutyl, 1,2-dihydroxyethyl, 1,3-dihydroxyisopropyl, 2,3-dihydroxy-t-butyl, 1,2,3-trihydroxypropyl, chloromethyl, 1-chloroethyl, 2-chloroethyl, 2-chloroisobutyl, 1,2-dichloroethyl, 1,3-dichloroisopropyl, 2,3-dichloro-t-butyl, 1,2,3-trichloropropyl, bromomethyl, 1-bromoethyl, 2-bromoethyl, 2-bromoisobutyl, 1,2-dibromoethyl, 1,3-dibromoisopropyl, 2,3-dibromo-t-butyl, 1,2,3-tribromopropyl, iodomethyl, 1-iodoethyl, 2-iodoethyl, 2-iodoisobutyl, 1,2-diiodoethyl, 1,3-diiodoisopropyl, 2,3-diiodo-t-butyl, 1,2,3-triiodopropyl, aminomethyl, 1-aminoethyl, 2-aminoethyl, 2-aminoisobutyl, 1,2-diaminoethyl, 1,3-diaminoisopropyl, 2,3-diamino-t-butyl, 1,2,3-triaminopropyl, cyanomethyl, 1-cyanoethyl, 2-cyanoethyl, 2-cyanoisobutyl, 1,2-dicyanoethyl, 1,3-dicyanoisopropyl, 2,3-dicyano-t-butyl, 1,2,3-tricyanopropyl, nitromethyl, 1-nitroethyl, 2-nitroethyl, 1,2-dinitroethyl, 2,3-dinitro-t-butyl, 1,2,3-trinitropropyl, cyclopentyl, cyclohexyl, cycloctyl, and 3,5-tetramethylcyclohexy.

Of them, methyl, ethyl, propyl, isopropyl, n-butyl, s-butyl, isobutyl, t-butyl, n-pentyl, n-hexyl, n-heptyl, n-octyl, n-nonyl, n-decyl, n-undecyl, n-dodecyl, n-tridecyl, n-tetradecyl, n-pentadecyl, n-hexadecyl, n-heptadecyl, n-octadecyl, neopentyl, 1-methylpentyl, 1-pentylhexyl, 1-butylpentyl, 1-heptyloctyl, cyclohexyl, cycloctyl, and 3,5-tetramethylcyclohexyl are preferable.

Examples of the alkyl halide group having 1 to 20 carbon atoms include fluoromethyl, difluoromethyl, trifluoromethyl, and pentafluoromethyl. Of them, fluoromethyl, difluoromethyl, and trifluoromethyl are preferable.

Examples of the alkoxy group having 1 to 20 carbon atoms include groups shown by —OY. Specific and preferred examples of Y are the same as those exemplified above as the specific and preferred examples of the alkyl group.

As examples of the arylamino group having 6 to 40 carbon atoms include diphenylamino, or phenyl, naphthyl, anthracenyl, triphenylenyl, fluoranthenyl, and biphenyl which each have diphenylamino or amino as a substituent can be given. Of them, phenyl and naphthyl having diphenylamino or amino as a substituent are preferable.

Examples of the aryl group having 6 to 40 ring carbon atoms include phenyl, naphthyl, biphenyl, antracenyl, and triphenylenyl. As the substituent, methyl, ethyl, cyclohexyl, isopropyl, butyl, phenyl, or the like can be given.

A substituted or unsubstituted phenyl, naphthyl, and biphenyl are preferable.

As examples of the heterocyclic residue having 2 to 40 ring carbon atoms, a 1-pyrrolyl, 2-pyrrolyl, 3-pyrrolyl, pyrazinyl, 2-pyridinyl, 1-imidazolyl, 2-imidazolyl, 1-pyrazolyl, 1-indolydinyl, 2-indolydinyl, 3-indolydinyl, 5-indolydinyl, 6-indoydinyl, 7-indolydinyl, 8-indolydinyl, 2-imidazopyridinyl, 3-imidazopyridinyl, 5-imidazopyridinyl, 6-imidazopyridinyl, 7-imidozopyridinyl, 8-imidazopyridinyl, 3-pyridinyl, 4-pyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, β-carbolin-1-yl, β-carbolin-3-yl, β-carbolin-4-yl, β-carbolin-5-yl, β-carbolin-6-yl, β-carbolin-7-yl, β-carbolin-6-yl, β-carbolin-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 1,7-phenanthrolin-2-yl, 1,7-phenanthrolin-3-yl, 1,7-phenanthrolin-4-yl, 1,7-phenanthrolin-5-yl, 1,7-phenanthrolin-6-yl, 1,7-phenanthrolin-8-yl, 1,7-phenanthrolin-9-yl, 1,7-phenanthrolin-10-yl, 1,8-phenanthrolin-2-yl, 1,8-phenanthrolin-3-yl, 1,8-phenanthrolin-4-yl, 1,8-phenanthrolin-5-yl, 1,8-phenanthrolin-6-yl, 1,8-phenanthrolin-7-yl, 1,8-phenanthrolin-9-yl, 1,8-phenanthrolin-10-yl, 1,9-phenanthrolin-2-yl, 1,9-phenanthrolin-3-yl, 1,9-phenanthrolin-4-yl, 1,9-phenanthrolin-5-yl, 1,9-phenanthrolin-6-yl, 1,9-phenanthrolin-7-yl, 1,9-phenanthrolin-8-yl, 1,9-phenanthrolin-10-yl, 1,10-phenanthrolin-2-yl, 1,10-phenanthrolin-3-yl, 1,10-phenanthrolin-4-yl, 1,10-phenanthrolin-5-yl, 2,9-phenanthrolin-1-yl, 2,9-phenanthrolin-3-yl, 2,9-phenanthrolin-4-yl, 2,9-phenanthrolin-5-yl, 2,9-phenanthrolin-6-yl, 2,9-phenanthrolin-7-yl, 2,9-phenanthrolin-8-yl, 2,9-phenanthrolin-10-yl, 2,8-phenanthrolin-1-yl, 2,8-phenanthrolin-3-yl, 2,8-phenanthrolin-4-yl, 2,8-phenanthrolin-5-yl, 2,8-phenanthrolin-6-yl, 2,8-phenanthrolin-7-yl, 2,8-phenanthrolin-9-yl, 2,8-phenanthrolin-10-yl, 2,7-phenanthrolin-1-yl, 2,7-phenanthrolin-3-yl, 2,7-phenanthrolin-4-yl, 2,7-phenanthrolin-5-yl, 2,7-phenanthrolin-6-yl, 2,7-phenanthrolin-8-yl, 2,7-phenanthrolin-9-yl, 2,7-phenanthrolin-10-yl, 1-phenazinyl, 2-phenazinyl, 1-phenothiadinyl, 2-phenothiadinyl, 3-phenothiadinyl, 4-phenothiadinyl, 10-phenothiadinyl, 1-phenoxadinyl, 2-phenoxadinyl, 3-phenoxadinyl, 4-phenoxadinyl, 10-phenoxadinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-t-butyl-pyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, 4-t-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl or the like can be given.

Of them, 2-pyridinyl, 1-indolydinyl, 2-indolydinyl, 3-indolydinyl, 5-indolydinyl, 6-indoydinyl, 7-indolydinyl, 8-indolydinyl, 2-imidazopyridinyl, 3-imidazopyridinyl, 5-imidazopyridinyl, 6-imidazopyridinyl, 7-imidozopyridinyl, 8-imidazopyridinyl, 3-pyridinyl, 4-pyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 1-carbazolyl, 2-carbazolyl, 3-carbazolyl, 4-carbazolyl, 9-carbazolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-silafluororenyl, 2-silafluorenyl, 3-silafluorenyl, 4-silafluorenyl, 1-germafluororenyl, 2-germafluororenyl, 3-germafluororenyl, and 4-germafluororenyl are preferable.

As the substituent, methyl, ethyl, cyclohexyl, isopropyl, butyl, phenyl or the like can be given.

R₁ and R₂ may be bonded to each other to form a ring. Examples of the ring include a benzene ring, a cyclohexyl ring, and a naphthyl ring.

In the formula (1), X is a single bond or a substituted or unsubstituted divalent group.

As the substituted or unsubstituted divalent group, a substituted or unsubstituted arylene group having 6 to 20 carbon atoms is preferable.

As the substituted or unsubstituted arylene group having 6 to 20 carbon atoms, phenylene, biphenylene, naphthylene, anthracenylene or the like can be given.

As the substituent, methyl, ethyl, phenyl, isopropyl, or the like can be given.

It is preferred that the derivative of the formula (1) have a structure represented by the following formula (2), in which X in the formula (1) is a substituted or unsubstituted phenylene group. 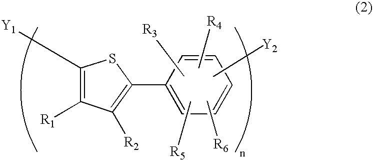
wherein R₃ to R₆ are independently a hydrogen atom, a cyano group, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms; adjacent substituents may be bonded to each other to form a ring; and R₁, R₂, Y₁, Y₂, and n are as defined in the above formula (1).

Specific examples of the alkyl group having 1 to 20 carbon atoms represented by R₃ to R₆, the alkyl halide group having 1 to 20 carbon atoms, the alkoxy group having 1 to 20 carbon atoms, the arylamino group having 6 to 40 carbon atoms, the substituted or unsubstituted aryl group having 6 to 40 ring carbon atoms, and the substituted or unsubstituted heterocyclic residue having 2 to 40 ring carbon atoms are the same as those exemplified for R₁ and R₂.

The structure represented by the following formula (3), in which X is a single bond, is also preferable. 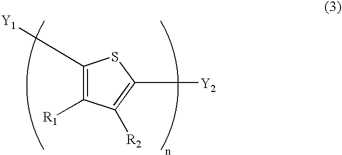
wherein R₁, R₂, Y₁, Y₂, and n are as defined in the above formula (1).

In the formula (1), Y₁ and Y₂ are independently a hydrogen atom, or a substituted or unsubstituted monovalent group. For example, it is preferred that Y₁ and Y₂ be selected from a hydrogen atom, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms.

Of them, a hydrogen atom, an alkyl group having 1 to 20 carbon atoms, a substituted or unsubstituted aryl group having 6 to 40 ring carbon atoms, and a substituted or unsubstituted heterocyclic residue having 2 to 40 ring carbon atoms are preferable.

Specific examples of the alkyl group having 1 to 20 carbon atoms, the alkyl halide group having 1 to 20 carbon atoms, the alkoxy group having 1 to 20 carbon atoms, the arylamino group having 6 to 40 carbon atoms, the substituted or unsubstituted aryl group having 6 to 40 ring carbon atoms, and the substituted or unsubstituted heterocyclic residue having 2 to 40 ring carbon atoms are the same as those exemplified for R₁ and R₂.

n is an integer of 1 to 20, preferably 1 to 8. When n is 2 or more, R₁s to R₆s and Xs may be the same or different.

In the invention, it is preferred that the thiophene derivative have a bithiophene structure, a terthiophene structure, or a quarterthiophene structure.

Specific examples of the thiophene derivatives represented by the formula (1) are given below.

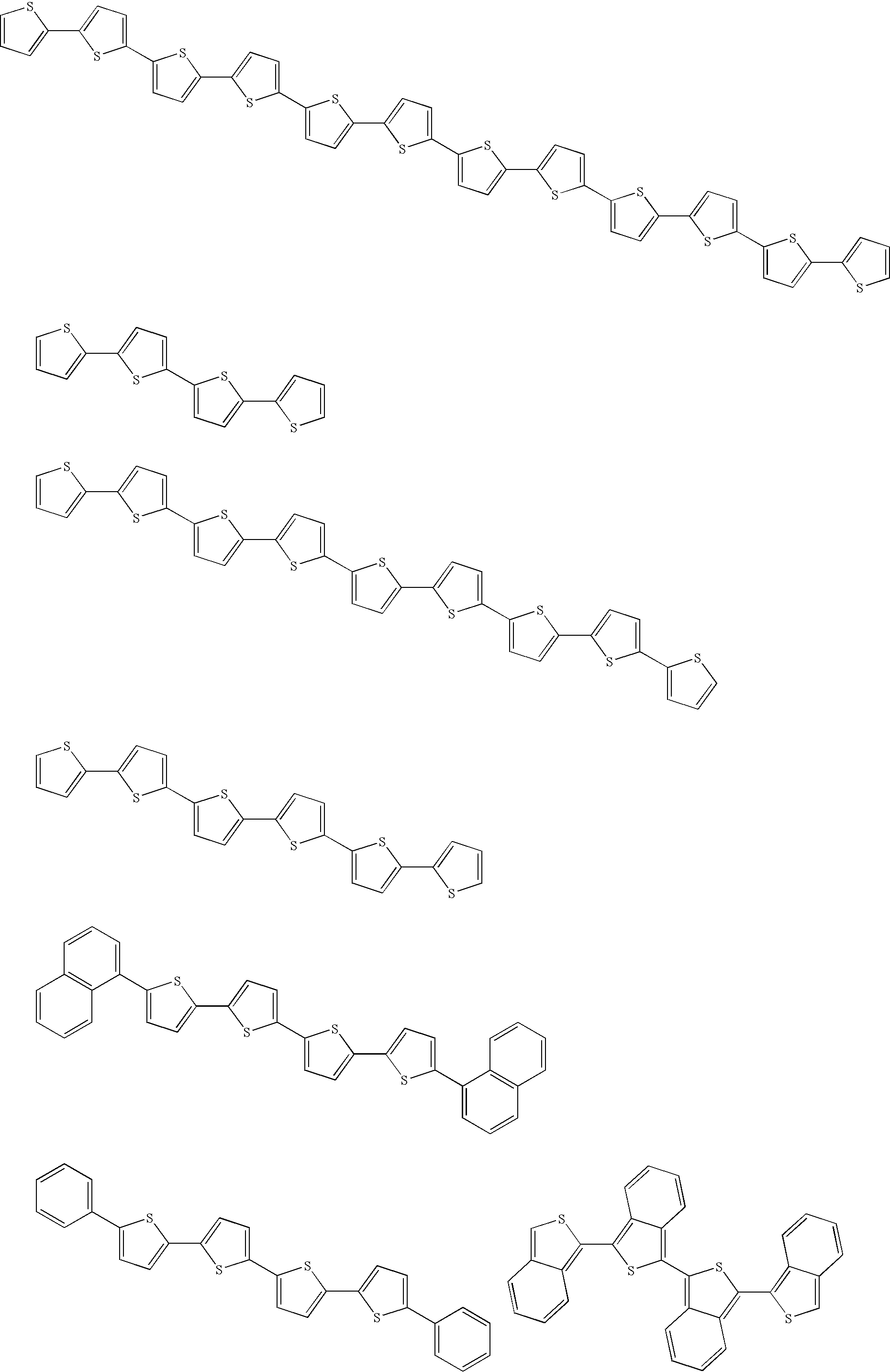

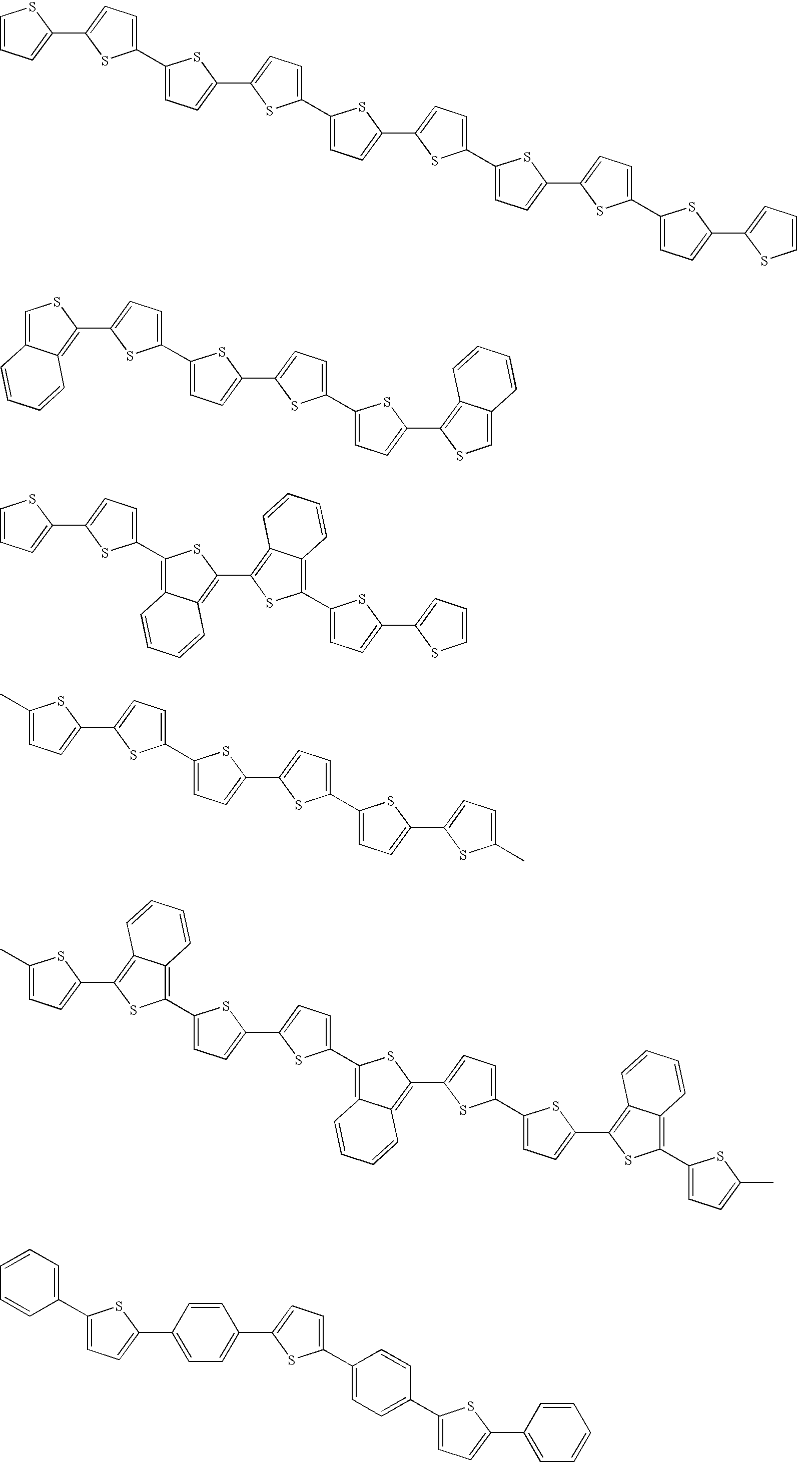

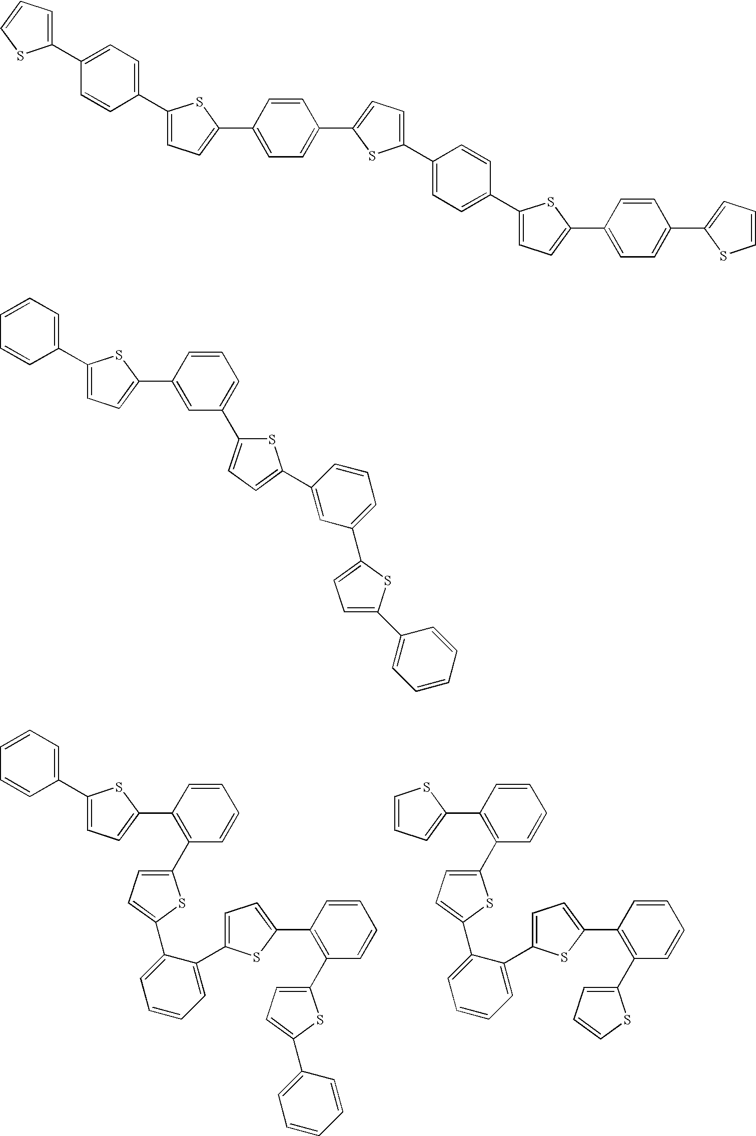

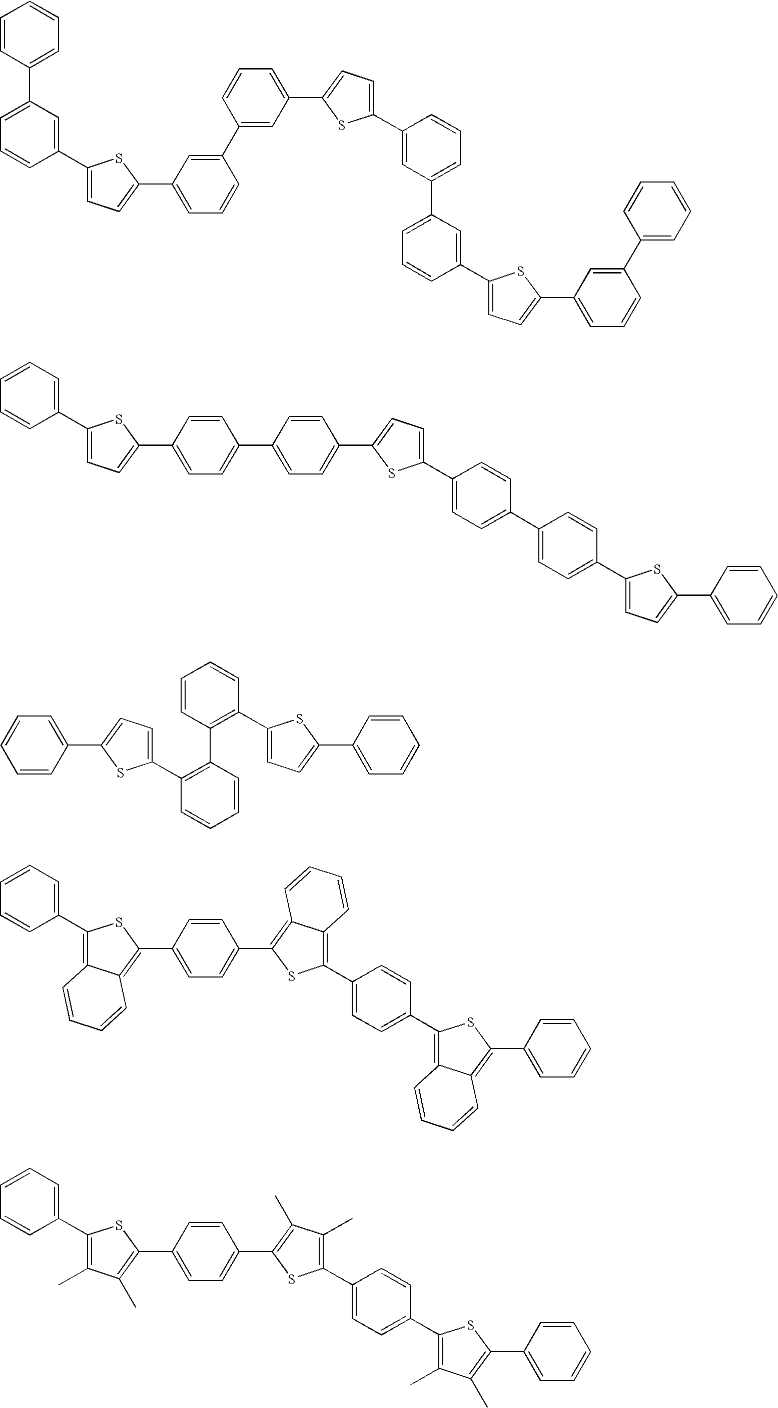

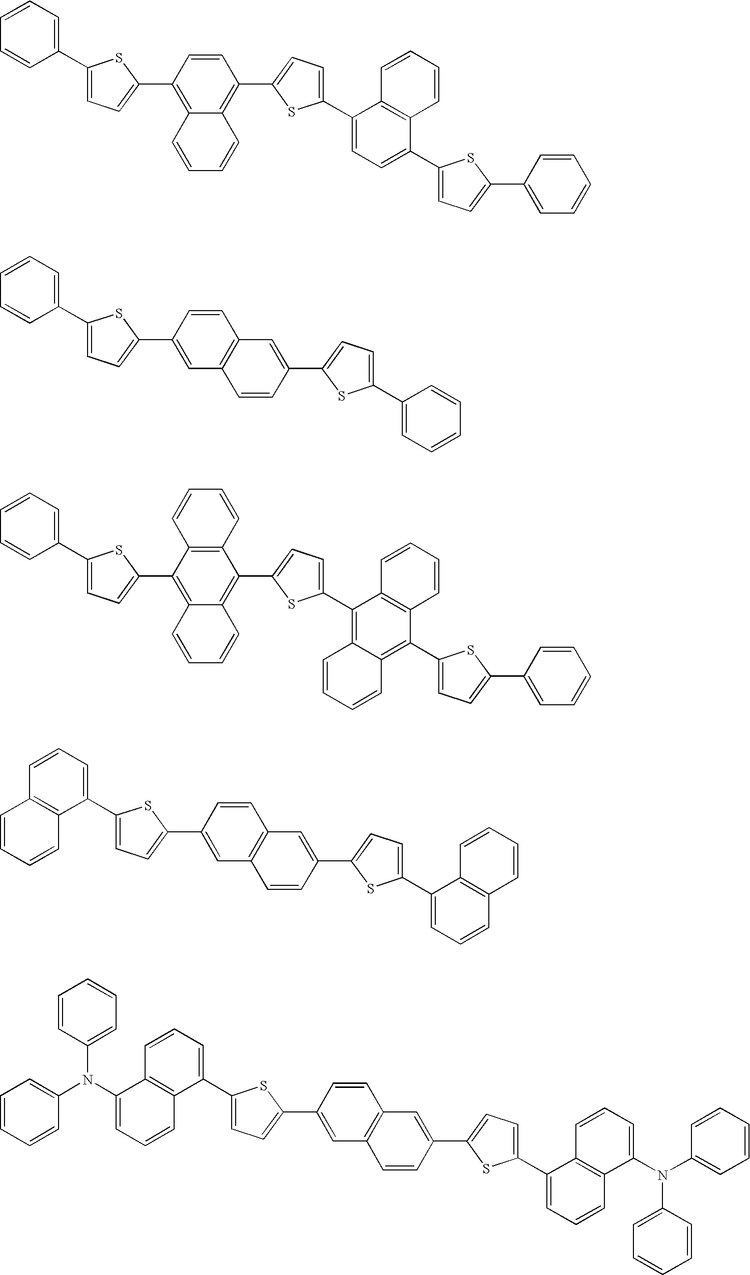

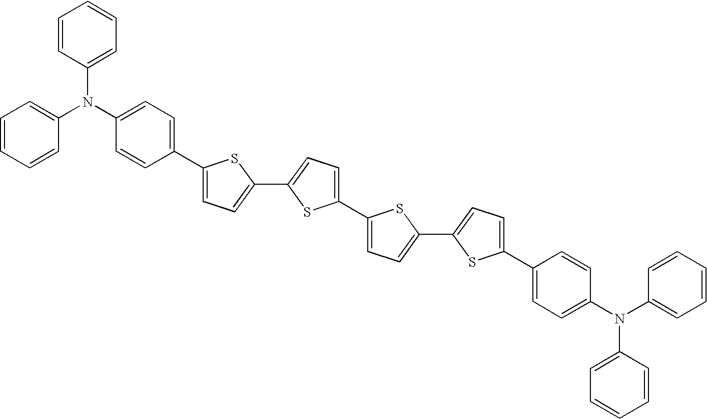

The thiophene derivative represented by the formula (1) may be one which is commercially available or one which is synthesized by a known method. For the synthesizing method, reference may be made to the Japanese Patent No. 2826381 or the like.

As the substance exhibiting electron acceptability for the thiophene derivative represented by the formula (1), an organic compound having an electron-attracting substituent or an electron-deficient ring, or a metal oxide can be used.

In the organic compound having an electron-attracting substituent or an electron-deficient ring, as examples of the electron-attracting substituent, halogen, cyano, trifluoromethyl, carbonyl, nitro, arylboron or the like can be given. In particular, cyano is preferable.

As examples of the electron-deficient ring, 2-pyridyl, 3-pyridyl, 4-pyridyl, 2-quinolyl, 3-quinolyl, 4-quinolyl, 2-imidazole, 4-imidazole, 3-pyrazole, 4-pyrazole, pyridazine, pyrimidine, pyrazine, cinnoline, phthalazine, quinazoline, quinoxaline, 3-(1,2,4-N)-triazolyl, 5-(1,2,4-N)-triazolyl, 5-tetrazolyl, 4-(1-O,3-N)-oxazole, 5-(1-O,3-N)-oxazole, 4-(1-5,3-N)-thiazole, 5-(1-5,3-N)-thiazole, 2-benzoxazole, 2-benzothiazole, 4-(1,2,3-N)-benzotriazole, benzimidazole, and the like can be given.

As the organic compound exhibiting electron acceptability for the thiophene derivative, quinoide derivatives, arylboran derivatives, thiopyrane dioxide derivatives, imide derivatives such as naphthalimide derivatives, and hexazatriphenylene derivatives are preferable.

For example, the following quinoide derivatives can be given.

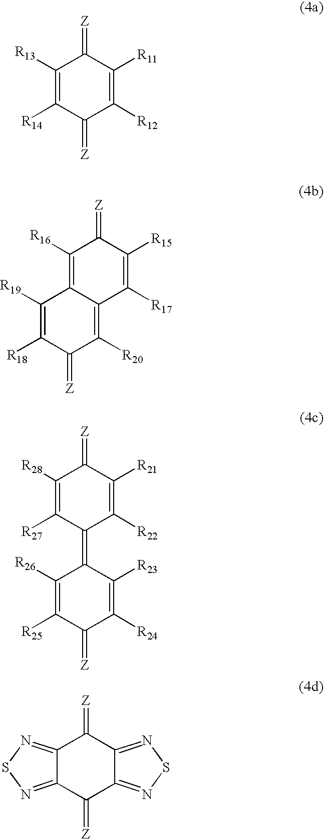

In the formulas, R₁₁ to R₂₈ are independently a hydrogen atom, a halogen atom, a fluoroalkyl group, a cyano group, an alkoxy group, an alkyl group, or an aryl group, excluding the derivatives where all of R₁₁, to R₂₈ are hydrogen in the same molecule.

As the halogen for R₁₁ to R₂₈, fluorine and chlorine are preferable.

As the fluoroalkyl group for R₁₁ to R₂₈, a trifluoromethyl group and a pentafluoroethyl group are preferable.

As the alkoxy group for R₁₁ to R₂₈, a methoxy group, an ethoxy group, an iso-propoxy group, and a tert-butoxy group are preferable.

As the alkyl group for R₁₁ to R₂₈, a methyl group, an ethyl group, a propyl group, an iso-propyl group, a tert-butyl group, and a cyclohexyl group are preferable.

As the aryl group for R₁₁ to R₂₈, a phenyl group and a naphthyl group are preferable.

Z is an electron-attracting group, and has a structure represented by one of the following structures (j) to (p). Note that the structures of the formulas (j), (k), and (1) are preferable. 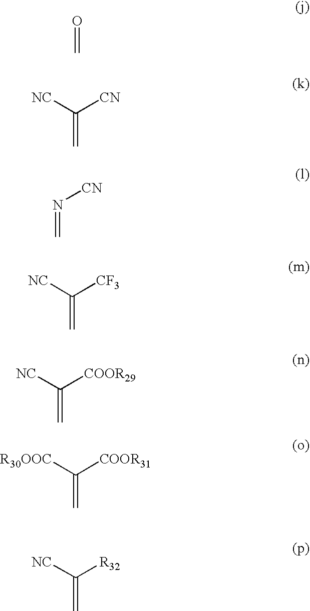
wherein R₂₉ to R₃₂ are independently a hydrogen atom, a fluoroalkyl group, an alkyl group, an aryl group, or a heterocyclic ring; and R₃₀ and R₃₁ may form a ring.

The fluoroalkyl group, alkyl group, and aryl group for R₂₉ to R₃₂ are the same as those for R₁₁ to R₂₈.

As the heterocyclic ring for R₂₉ to R₃₂, substituents of the following formulas are preferable.

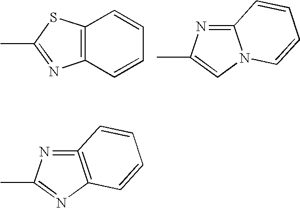

When R₃₀ and R₃₁ form a ring, Z is preferably a substituent of the following formula. 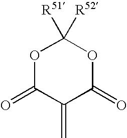
wherein R^{51′} and R^{52′} are independently a methyl group, an ethyl group, a propyl group, or a tert-butyl group.

In the invention, of the above-mentioned electron-acceptable compounds, one which contains a cyano group is particularly preferable.

Specific examples of the quinoide derivative which exhibits electron acceptability for the thiophene derivative are shown below.

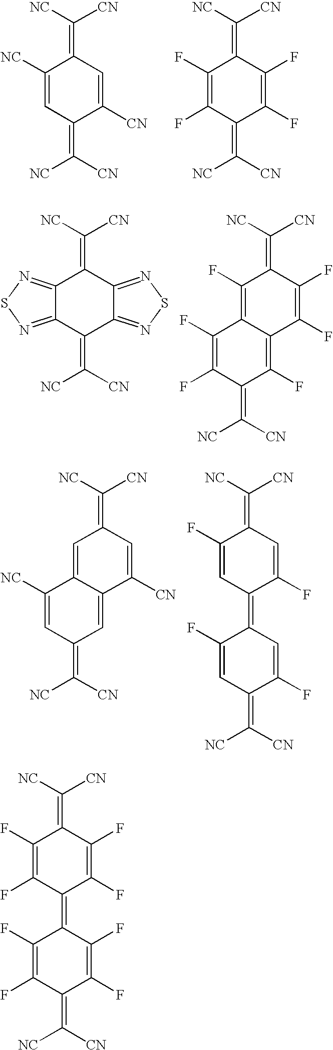

The compounds of the following formula (5) can also be given. 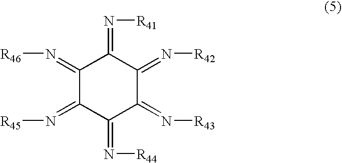
wherein R₄₁, R₄₂, R₄₃, R₄₄, R₄₅ and R₄₆ are one of a substituted or unsubstituted alkyl group, a substituted or unsubstituted aryl group, a substituted or unsubstituted aralkyl group, and a substituted or unsubstituted heterocyclic group; R₄₁, R₄₂, R₄₃, R₄₄, R₄₅ and R₄₆ may be the same or different; R₄₁ and R₄₂, R₄₃ and R₄₄, R₄₅ and R₄₆, or R₄₁ and R₄₆, R₄₂ and R₄₃, or R₄₄ and R₄₅ may form a condensed ring.

A compound of the following formula (6) is preferable. 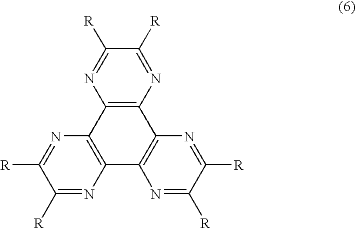
wherein Rs are independently a halogen atom, a cyano group, a nitro group, an alkyl group, a trifluoromethyl group, an aryloxycarbonyl group, an alkoxycarbonyl group, a dialkylcarbamoyl group, a diarylcarbamoyl group, or a carboxyl group.

It is particularly preferred that R be a cyano group.

As examples of the metal oxide exhibiting electron acceptability for the thiophene derivative, an oxide of a transition metal belonging to the groups 4 to 12 of the periodic table can be given. An oxide of a transition metal belonging to the groups 4 to 8 of the periodic table is preferable.

Specific examples of the preferable metal oxide include a molybdenum oxide (MoOx), a vanadium oxide (VOx), a ruthenium oxide (RuOx), a tungsten oxide (WOx), a rhenium oxide (ReOx), a titanium oxide (TiOx), a chromium oxide (CrOx), a zirconium oxide (ZrOx), a hafnium oxide (HfOx), and tantalum oxide (TaOx). x in the composition formulas is a number of 2 to 3.

The organic compound or the metal oxide exhibiting electron acceptability for the above-mentioned thiophene derivative may be used singly or in combination of two or more.

The substance exhibiting electron acceptability for the thiophene derivative shown in the formula (1) is contained preferably in an amount of 1 to 60 mol %, more preferably 1 to 40 mol %, when expressed in molar weight fraction, relative to the derivative shown in the formula (1).

The thiophene derivative and the substance exhibiting electron acceptability for the thiophene derivative may form a layer. The layer may be formed by mixing materials constituting the layers described later.

The structure of the luminescent device of the invention is not limited to the embodiment shown in FIG. 1 as mentioned above. For example, the luminescent device of the invention may have structures (1) to (14) shown below.

(1) Anode/hole-transporting layer/emitting layer/cathode

(2) Anode/emitting layer/electron-transporting layer/cathode

(3) Anode/hole-transporting layer/emitting layer/electron-transporting layer/cathode

(4) Anode/hole-transporting layer/emitting layer/adhesion-improving layer/cathode

(5) Anode/hole-injecting layer/hole-transporting layer/emitting layer/electron-transporting layer/cathode (FIG. 1)

(6) Anode/hole-transporting layer/emitting layer/electron-transporting layer/electron-injecting layer/cathode

(7) Anode/hole-injecting layer/hole-transporting layer/emitting layer/electron-transporting layer/electron-injecting layer/cathode

(8) Anode/insulative layer/hole-transporting layer/emitting layer/electron-transporting layer/cathode

(9) Anode/hole-transporting layer/emitting layer/electron-transporting layer/insulative layer/cathode

(10) Anode/inorganic semiconductor layer/insulative layer/hole-transporting layer/emitting layer/insulative layer/cathode

(11) Anode/insulative layer/hole-transporting layer/emitting layer/electron-transporting layer/insulative layer/cathode

(12) Anode/hole-injecting layer/hole-transporting layer/emitting layer/electron-transporting layer/insulative layer/cathode

(13) Anode/insulative layer/hole-injecting layer/hole-transporting layer/emitting layer/electron-transporting layer/electron-injecting layer/cathode

(14) Anode/insulative layer/hole-injecting layer/hole-transporting layer/emitting layer/electron-transporting layer/electron-injecting layer/insulative layer/cathode

In the invention, of the layers interposed between the anode and the cathode in the above-mentioned structures, at least one layer contains the above-mentioned thiophene derivative and the substance exhibiting electron acceptability for the thiophene derivative.

Among these, usually, the structures (3), (5), (6), (7), (11), (12) and (14) are preferably used.

Each member constituting the luminescent device of the invention is described below.

(Transparent Substrate)

The luminescent device of the invention is formed on a transparent substrate. The transparent substrate as referred to herein is a substrate for supporting the luminescent device, and is preferably a flat and smooth substrate having a transmittance of 50% or more to light rays within visible ranges of 400 to 700 nm.

Specific examples thereof include glass plates and polymer plates. Examples of the glass plate include soda-lime glass, barium/strontium-containing glass, lead glass, aluminosilicate glass, borosilicate glass, barium borosilicate glass, and quartz. Examples of the polymer plate include polycarbonate, acrylic polymer, polyethylene terephthalate, polyethersulfide, and polysulfone.

Transparency is not required when the supporting substrate is positioned in the direction opposite to the light-outcoupling direction.

(Anode)

The anode plays a role for injecting holes into its hole-transporting layer or emitting layer. When transparency is required for the anode, indium tin oxide alloy (ITO), tin oxide (NESA), indium zinc oxide alloy (IZO), gold, silver, platinum, copper, and the like may be used as the material for the anode. When a reflective electrode which does not require transparency is used, in addition to the above metals, a metal such as aluminum, molybdenum, chromium, and nickel or alloys thereof may also be used.

Although these materials may be used singly, alloys thereof or materials wherein another element is added to the materials can be appropriately selected for use.

The anode can be formed by forming these electrode materials into a thin film by vapor deposition, sputtering or the like.

In the case where emission from the emitting layer is taken out through the anode, the transmittance of the anode to the emission is preferably more than 10%. The sheet resistance of the anode is preferably several hundreds Ω/□ or less. The film thickness of the anode, which varies depending upon the material thereof, is usually from 10 nm to 1 μm, preferably from 10 to 200 nm.

(Emitting Layer)

The emitting layer has the following functions in combination.

(1) Injection function: function of allowing injection of holes from the anode or hole-injecting/transporting layer and injection of electrons from the cathode or electron-injecting/transporting layer upon application of an electric field

(2) Transporting function: function of moving injected carriers (electrons and holes) due to the force of an electric field

(3) Emitting function: function of allowing electrons and holes to recombine therein to emit light

Note that electrons and holes may be injected into the emitting layer with different degrees, or the transportation capabilities indicated by the mobility of holes and electrons may differ. It is preferable that the emitting layer move either electrons or holes.

As the material used for the emitting layer, a known long-lived luminescent material may be used. It is preferable to use a material of the general formula (1) as the luminescent material. 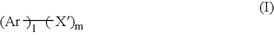
wherein Ar is an aromatic ring with 6 to 50 ring carbon atoms or an aromatic heteroring having 5 to 50 ring atoms, X′ is a substituent, l is an integer of 1 to 5, and m is an integer of 0 to 6.

As specific examples of the aromatic ring and aromatic heteroring shown by Ar, a phenyl ring, a naphthyl ring, an anthracene ring, a biphenylene ring, an azulene ring, an acenaphthylene ring, a fluorene ring, a phenanthrene ring, a fluoranthene ring, an acephenantrylene ring, a triphenylene ring, a pyrene ring, a chrysene ring, a benzanthracene ring, a naphthacene ring, a picene ring, a perylene ring, a pentaphene ring, a pentacene ring, a tetraphenylene ring, a hexaphene ring, a hexacene ring, a rubicene ring, a coronene ring, a trinaphthylene ring, a pyrrole ring, an indole ring, a carbazole ring, an imidazole ring, a benzimidazole ring, an oxadiazole ring, a triazole ring, a pyridine ring, a quinoxaline ring, a quinoline ring, a pyrimidine ring, a triazine ring, a thiophene ring, a benzothiophene ring, a thianthrene ring, a furan ring, a benzofuran ring, a pyrazole ring, a pyrazine ring, a pyridazine ring, an indolizine ring, a quinazoline ring, a phenanthroline ring, a silole ring, a benzosilole ring, and the like can be given.

Ar is preferably a phenyl ring, a naphthyl ring, an anthracene ring, an acenaphthylene ring, a fluorene ring, a phenanthrene ring, a fluoranthene ring, a triphenylene ring, a pyrene ring, a chrysene ring, a benzanthracene ring, or a perylene ring.

Specific examples of the substituent represented by X include a substituted or unsubstituted aromatic group having 6 to 50 ring carbon atoms, a substituted or unsubstituted aromatic heterocyclic group having 5 to 50 ring atoms, a substituted or unsubstituted alkyl group having 1 to 50 carbon atoms, a substituted or unsubstituted alkoxy group having 1 to 50 carbon atoms, a substituted or unsubstituted aralkyl group having 1 to 50 carbon atoms, a substituted or unsubstituted aryloxy group having 5 to 50 ring atoms, a substituted or unsubstituted arylthio group having 5 to 50 ring atoms, a substituted or unsubstituted carboxyl group having 1 to 50 carbon atoms, a substituted or unsubstituted styryl group, a halogen group, a cyano group, a nitro group and a hydroxyl group.

As examples of the substituted or unsubstituted aromatic group having 6 to 50 ring carbon atoms, a phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 3-methyl-2-naphthyl group, 4-methyl-1-naphthyl group, 4-methyl-1-anthryl group, 4′-methylbiphenylyl group, 4″-t-butyl-p-terphenyl-4-yl group, 2-fluorenyl group, 9,9-dimethyl-2-fluorenyl group, 3-fluoranthenyl group, and the like can be given.

The substituted or unsubstituted aromatic group having 6 to 50 ring carbon atoms is preferably a phenyl group, 1-naphthyl group, 2-naphthyl group, 9-phenanthryl group, 1-naphthacenyl group, 2-naphthacenyl group, 9-naphthacenyl group, 1-pyrenyl group, 2-pyrenyl group, 4-pyrenyl group, 2-biphenylyl group, 3-biphenylyl group, 4-biphenylyl group, o-tolyl group, m-tolyl group, p-tolyl group, p-t-butylphenyl group, 2-fluorenyl group, 9,9-dimethyl-2-fluorenyl group, 3-fluoranthenyl group, or the like.

As examples of the substituted or unsubstituted aromatic heterocyclic group having 5 to 50 ring atoms, a 1-pyrrolyl group, 2-pyrrolyl group, 3-pyrrolyl group, pyrazinyl group, 2-pyridinyl group, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 9-carbazolyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, 9-acridinyl group, 1,7-phenanthrolin-2-yl group, 1,7-phenanthrolin-3-yl group, 1,7-phenanthrolin-4-yl group, 1,7-phenanthrolin-5-yl group, 1,7-phenanthrolin-6-yl group, 1,7-phenanthrolin-8-yl group, 1,7-phenanthrolin-9-yl group, 1,7-phenanthrolin-10-yl group, 1,8-phenanthrolin-2-yl group, 1,8-phenanthrolin-3-yl group, 1,8-phenanthrolin-4-yl group, 1,8-phenanthrolin-5-yl group, 1,8-phenanthrolin-6-yl group, 1,8-phenanthrolin-7-yl group, 1,8-phenanthrolin-9-yl group, 1,8-phenanthrolin-10-yl group, 1,9-phenanthrolin-2-yl group, 1,9-phenanthrolin-3-yl group, 1,9-phenanthrolin-4-yl group, 1,9-phenanthrolin-5-yl group, 1,9-phenanthrolin-6-yl group, 1,9-phenanthrolin-7-yl group, 1,9-phenanthrolin-8-yl group, 1,9-phenanthrolin-10-yl group, 1,10-phenanthrolin-2-yl group, 1,10-phenanthrolin-3-yl group, 1,10-phenanthrolin-4-yl group, 1,10-phenanthrolin-5-yl group, 2,9-phenanthrolin-1-yl group, 2,9-phenanthrolin-3-yl group, 2,9-phenanthrolin-4-yl group, 2,9-phenanthrolin-5-yl group, 2,9-phenanthrolin-6-yl group, 2,9-phenanthrolin-7-yl group, 2,9-phenanthrolin-8-yl group, 2,9-phenanthrolin-10-yl group, 2,8-phenanthrolin-1-yl group, 2,8-phenanthrolin-3-yl group, 2,8-phenanthrolin-4-yl group, 2,8-phenanthrolin-5-yl group, 2,8-phenanthrolin-6-yl group, 2,8-phenanthrolin-7-yl group, 2,8-phenanthrolin-9-yl group, 2,8-phenanthrolin-10-yl group, 2,7-phenanthrolin-1-yl group, 2,7-phenanthrolin-3-yl group, 2,7-phenanthrolin-4-yl group, 2,7-phenanthrolin-5-yl group, 2,7-phenanthrolin-6-yl group, 2,7-phenanthrolin-8-yl group, 2,7-phenanthrolin-9-yl group, 2,7-phenanthrolin-10-yl group, 1-phenazinyl group, 2-phenazinyl group, 1-phenothiadinyl group, 2-phenothiadinyl group, 3-phenothiadinyl group, 4-phenothiadinyl group, 10-phenothiadinyl group, 1-phenoxadinyl group, 2-phenoxadinyl group, 3-phenoxadinyl group, 4-phenoxadinyl group, 10-phenoxadinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrol-1-yl group, 2-methylpyrrol-3-yl group, 2-methylpyrrol-4-yl group, 2-methylpyrrol-5-yl group, 3-methylpyrrol-1-yl group, 3-methylpyrrol-2-yl group, 3-methylpyrrol-4-yl group, 3-methylpyrrol-5-yl group, 2-t-butyl-pyrrol-4-yl group, 3-(2-phenylpropyl)pyrrol-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, 4-t-butyl-3-indolyl group, and the like can be given.

As examples of the substituted or unsubstituted alkyl group having 1 to 50 carbon atoms, a methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinitroisopropyl group, 2,3-dinitro-t-butyl group, 1,2,3-trinitropropyl group, cyclopropyl group, cyclobutyl group, cyclopentyl group, cyclohexyl group, 4-methylcyclohexyl group, 1-adamantyl group, 2-adamantyl group, 1-norbornyl group, 2-norbornyl group, and the like can be given.

The substituted or unsubstituted alkoxy group having 1 to 50 carbon atoms is a group shown by —OY. As examples of Y, a methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinitroisopropyl group, 2,3-dinitro-t-butyl group, 1,2,3-trinitropropyl group, and the like can be given.

As examples of the substituted or unsubstituted aralkyl group having 1 to 50 carbon atoms, a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, 2-β-naphthylisopropyl group, 1-pyrrolylmethyl group, 2-(1-pyrrolyl)ethyl group, p-methylbenzyl group, m-methylbenzyl group, o-methylbenzyl group, p-chlorobenzyl group, m-chlorobenzyl group, o-chlorobenzyl group, p-bromobenzyl group, m-bromobenzyl group, o-bromobenzyl group, p-iodobenzyl group, m-iodobenzyl group, o-iodobenzyl group, p-hydroxybenzyl group, m-hydroxybenzyl group, o-hydroxybenzyl group, p-aminobenzyl group, m-aminobenzyl group, o-aminobenzyl group, p-nitrobenzyl group, m-nitrobenzyl group, o-nitrobenzyl group, p-cyanobenzyl group, m-cyanobenzyl group, o-cyanobenzyl group, 1-hydroxy-2-phenylisopropyl group, 1-chloro-2-phenylisopropyl group and the like can be given.

The substituted or unsubstituted aryloxy group having 5 to 50 ring atoms is shown by —OY′. As examples of Y′, a phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 3-methyl-2-naphthyl group, 4-methyl-1-naphthyl group, 4-methyl-1-anthryl group, 4′-methylbiphenylyl group, 4″-t-butyl-p-terphenyl-4-yl group, 2-pyrrolyl group, 3-pyrrolyl group, pyrazinyl group, 2-pyridinyl group, 3-pyridinyl group, 4-pyridinyl group, 2-indolyl group, 3-indolyl group, 4-indolyl group, 5-indolyl group, 6-indolyl group, 7-indolyl group, 1-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, 9-acridinyl group, 1,7-phenanthrolin-2-yl group, 1,7-phenanthrolin-3-yl group, 1,7-phenanthrolin-4-yl group, 1,7-phenanthrolin-5-yl group, 1,7-phenanthrolin-6-yl group, 1,7-phenanthrolin-8-yl group, 1,7-phenanthrolin-9-yl group, 1,7-phenanthrolin-10-yl group, 1,8-phenanthrolin-2-yl group, 1,8-phenanthrolin-3-yl group, 1,8-phenanthrolin-4-yl group, 1,8-phenanthrolin-5-yl group, 1,8-phenanthrolin-6-yl group, 1,8-phenanthrolin-7-yl group, 1,8-phenanthrolin-9-yl group, 1,8-phenanthrolin-10-yl group, 1,9-phenanthrolin-2-yl group, 1,9-phenanthrolin-3-yl group, 1,9-phenanthrolin-4-yl group, 1,9-phenanthrolin-5-yl group, 1,9-phenanthrolin-6-yl group, 1,9-phenanthrolin-7-yl group, 1,9-phenanthrolin-8-yl group, 1,9-phenanthrolin-10-yl group, 1,10-phenanthrolin-2-yl group, 1,10-phenanthrolin-3-yl group, 1,10-phenanthrolin-4-yl group, 1,10-phenanthrolin-5-yl group, 2,9-phenanthrolin-1-yl group, 2,9-phenanthrolin-3-yl group, 2,9-phenanthrolin-4-yl group, 2,9-phenanthrolin-5-yl group, 2,9-phenanthrolin-6-yl group, 2,9-phenanthrolin-7-yl group, 2,9-phenanthrolin-8-yl group, 2,9-phenanthrolin-10-yl group, 2,8-phenanthrolin-1-yl group, 2,8-phenanthrolin-3-yl group, 2,8-phenanthrolin-4-yl group, 2,8-phenanthrolin-5-yl group, 2,8-phenanthrolin-6-yl group, 2,8-phenanthrolin-7-yl group, 2,8-phenanthrolin-9-yl group, 2,8-phenanthrolin-10-yl group, 2,7-phenanthrolin-1-yl group, 2,7-phenanthrolin-3-yl group, 2,7-phenanthrolin-4-yl group, 2,7-phenanthrolin-5-yl group, 2,7-phenanthrolin-6-yl group, 2,7-phenanthrolin-8-yl group, 2,7-phenanthrolin-9-yl group, 2,7-phenanthrolin-10-yl group, 1-phenazinyl group, 2-phenazinyl group, 1-phenothiadinyl group, 2-phenothiadinyl group, 3-phenothiadinyl group, 4-phenothiadinyl group, 1-phenoxadinyl group, 2-phenoxadinyl group, 3-phenoxadinyl group, 4-phenoxadinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrol-1-yl group, 2-methylpyrrol-3-yl group, 2-methylpyrrol-4-yl group, 2-methylpyrrol-5-yl group, 3-methylpyrrol-1-yl group, 3-methylpyrrol-2-yl group, 3-methylpyrrol-4-yl group, 3-methylpyrrol-5-yl group, 2-t-butylpyrrol-4-yl group, 3-(2-phenylpropyl)pyrrol-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, 4-t-butyl-3-indolyl group, and the like can be given.

The substituted or unsubstituted arylthio group having 5 to 50 ring atoms is shown by —SY″. As examples of Y″, a phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 3-methyl-2-naphthyl group, 4-methyl-1-naphthyl group, 4-methyl-1-anthryl group, 4′-methylbiphenylyl group, 4″-t-butyl-p-terphenyl-4-yl group, 2-pyrrolyl group, 3-pyrrolyl group, pyrazinyl group, 2-pyridinyl group, 3-pyridinyl group, 4-pyridinyl group, 2-indolyl group, 3-indolyl group, 4-indolyl group, 5-indolyl group, 6-indolyl group, 7-indolyl group, 1-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, 9-acridinyl group, 1,7-phenanthrolin-2-yl group, 1,7-phenanthrolin-3-yl group, 1,7-phenanthrolin-4-yl group, 1,7-phenanthrolin-5-yl group, 1,7-phenanthrolin-6-yl group, 1,7-phenanthrolin-8-yl group, 1,7-phenanthrolin-9-yl group, 1,7-phenanthrolin-10-yl group, 1,8-phenanthrolin-2-yl group, 1,8-phenanthrolin-3-yl group, 1,8-phenanthrolin-4-yl group, 1,8-phenanthrolin-5-yl group, 1,8-phenanthrolin-6-yl group, 1,8-phenanthrolin-7-yl group, 1,8-phenanthrolin-9-yl group, 1,8-phenanthrolin-10-yl group, 1,9-phenanthrolin-2-yl group, 1,9-phenanthrolin-3-yl group, 1,9-phenanthrolin-4-yl group, 1,9-phenanthrolin-5-yl group, 1,9-phenanthrolin-6-yl group, 1,9-phenanthrolin-7-yl group, 1,9-phenanthrolin-8-yl group, 1,9-phenanthrolin-10-yl group, 1,10-phenanthrolin-2-yl group, 1,10-phenanthrolin-3-yl group, 1,10-phenanthrolin-4-yl group, 1,10-phenanthrolin-5-yl group, 2,9-phenanthrolin-1-yl group, 2,9-phenanthrolin-3-yl group, 2,9-phenanthrolin-4-yl group, 2,9-phenanthrolin-5-yl group, 2,9-phenanthrolin-6-yl group, 2,9-phenanthrolin-7-yl group, 2,9-phenanthrolin-8-yl group, 2,9-phenanthrolin-10-yl group, 2,8-phenanthrolin-1-yl group, 2,8-phenanthrolin-3-yl group, 2,8-phenanthrolin-4-yl group, 2,8-phenanthrolin-5-yl group, 2,8-phenanthrolin-6-yl group, 2,8-phenanthrolin-7-yl group, 2,8-phenanthrolin-9-yl group, 2,8-phenanthrolin-10-yl group, 2,7-phenanthrolin-1-yl group, 2,7-phenanthrolin-3-yl group, 2,7-phenanthrolin-4-yl group, 2,7-phenanthrolin-5-yl group, 2,7-phenanthrolin-6-yl group, 2,7-phenanthrolin-8-yl group, 2,7-phenanthrolin-9-yl group, 2,7-phenanthrolin-10-yl group, 1-phenazinyl group, 2-phenazinyl group, 1-phenothiadinyl group, 2-phenothiadinyl group, 3-phenothiadinyl group, 4-phenothiadinyl group, 1-phenoxadinyl group, 2-phenoxadinyl group, 3-phenoxadinyl group, 4-phenoxadinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrol-1-yl group, 2-methylpyrrol-3-yl group, 2-methylpyrrol-4-yl group, 2-methylpyrrol-5-yl group, 3-methylpyrrol-1-yl group, 3-methylpyrrol-2-yl group, 3-methylpyrrol-4-yl group, 3-methylpyrrol-5-yl group, 2-t-butyl-pyrrol-4-yl group, 3-(2-phenylpropyl)pyrrol-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, 4-t-butyl-3-indolyl group, and the like can be given.

The substituted or unsubstituted carboxyl group having 1 to 50 carbon atoms is shown by —COOZ. As examples of Z, a methyl group, ethyl group, propyl group, isopropyl group, n-butyl group, s-butyl group, isobutyl group, t-butyl group, n-pentyl group, n-hexyl group, n-heptyl group, n-octyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 2-nitroisobutyl group, 1,2-dinitroethyl group, 1,3-dinitroisopropyl group, 2,3-dinitro-t-butyl group, 1,2,3-trinitropropyl group, and the like can be given.

As examples of the substituted or unsubstituted styryl group, 2-phenyl-1-vinyl group, 2,2-diphenyl-1-vinyl group, 1,2,2-triphenyl-1-vinyl group, and the like can be given.

As examples of the halogen group, fluorine, chlorine, bromine, iodine, and the like can be given.

m is preferably 1 to 2. n is preferably 0 to 4. When m≧2, the Ars in the formula (1) may be the same or different. When n≧2, the Xs in the formula (1) may be the same or different.

As the material used in the emitting layer, it is further preferable to use an anthracene derivative represented by the following formula (II).
A¹-L-A² (II)
wherein A¹ and A² are independently a substituted or unsubstituted monophenylanthryl group or a substituted or unsubstituted diphenylanthryl group, and may be the same or different; and L is a single bond or a divalent linking group.

In addition to the anthracene derivative described above, an anthracene derivative represented by the formula (III) can be given.
A³-An-A⁴ (III)
wherein An is a substituted or unsubstituted divalent anthracene residue; and A³ and A⁴ are independently a substituted or unsubstituted monovalent condensed aromatic ring or a substituted or unsubstituted non-condensed ring aryl group having 12 or more carbon atoms and may be the same or different.

As the preferable anthracene derivative represented by the formula (II), anthracene derivatives represented by the formula (II-a) or the formula (II-b) can be given, for example. 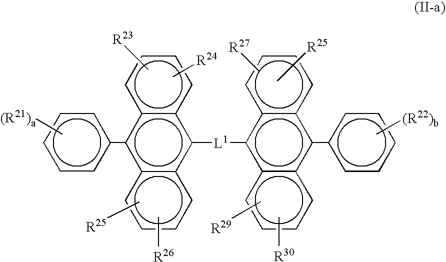
wherein R²¹ to R³⁰ are independently a hydrogen atom, an alkyl group, a cycloalkyl group, an aryl group which may be substituted, an alkoxy group, an aryloxy group, an alkylamino group, an arylamino group or a heterocyclic group which may be substituted; a and b are each an integer of 1 to 5; when they are 2 or more, R²¹ s or R²²s may be the same or different, or R²¹ s or R²²s may be bonded to each other to form a ring; R²³ and R²⁴, R²⁵ and R²⁶, R²⁷ and R²⁸, or R²⁹ and R³⁰ may be bonded to each other to form a ring; and L¹ is a single bond, —O—, —S—, —N(R)— (R is an alkyl group or an aryl group which may be substituted), or an arylene group. 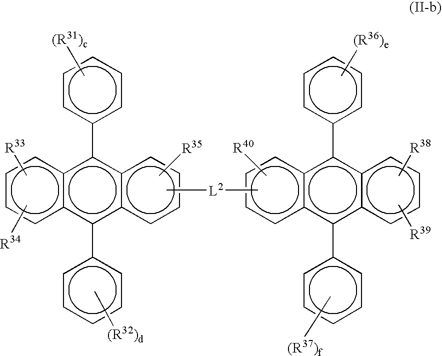
wherein R³¹ to R⁴⁰ are independently a hydrogen atom, an alkyl group, a cycloalkyl group, an aryl group which may be substituted, an alkoxy group, an aryloxy group, an alkylamino group, an arylamino group or a heterocyclic group which may be substituted; c, d, e and f are each an integer of 1 to 5; when they are 2 or more, R³¹s, R³²s, R³⁶s or R³⁷s may be the same or different, R³¹s, R³²s, R³⁶s or R³⁷s may be bonded to each other to form a ring, or R³³ and R³⁴, or R³⁸ and R³⁹ may be bonded to each other to form a ring; and L² is a single bond, —O—, —S—, —N(R)— (R is an alkyl group or an aryl group which may be substituted), or an arylene group.

Here, the term “may be substituted” means “a substituted or unsubstituted”.

As for R²¹ to R⁴⁰ shown in the above formulas (II-a) and (II-b), as the alkyl group, an alkyl group having 1 to 6 carbon atoms, as the cycloalkyl group, a cycloalkyl group having 3 to 6 carbon atoms, as the aryl group, an aryl group having 5 to 18 carbon atoms, as the alkoxy group, an alkoxy group having 1 to 6 carbon atoms, as the aryloxy group, an aryloxy group having 5 to 18 carbon atoms, as the arylamino group, an amino group substituted with an aryl group having 5 to 16 carbon atoms, as the heterocyclic group, triazole, oxadiazole, quinoxaline, furanyl, thienyl or the like can preferably be given.

As the alkyl group and the aryl group shown by R in —N(R)—in L¹ and L², an alkyl group having 1 to 6 carbon atoms and an aryl group having 5 to 18 carbon atoms are preferable.

Also, a metal complex of 8-hydroxyquinoline or a derivative thereof is preferable.

As specific examples of the metal complex of 8-hydroxyquinoline and its derivative, metal chelate oxynoid compounds including a chelate of oxine (generally, 8-quinolinol or 8-hydroxyquinoline) can be given.

In the emitting layer, its emission performance can be improved by adding a fluorescent compound as a dopant. Dopants known as a dopant material having a long lifetime may be used. It is preferable to use, as the dopant material of the luminescent material, a material represented by the formula (IV): 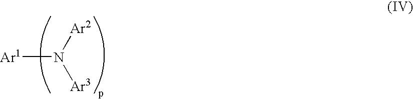
wherein Ar¹ to Ar³ are independently a substituted or unsubstituted aromatic group with 6 to 50 ring carbon atoms, or a substituted or unsubstituted styryl group.

As examples of the substituted or unsubstituted aromatic group having 6 to 50 ring carbon atoms, a phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 3-methyl-2-naphthyl group, 4-methyl-1-naphthyl group, 4-methyl-1-anthryl group, 4′-methylbiphenylyl group, 4″-t-butyl-p-terphenyl-4-yl group, 2-fluorenyl group, 9,9-dimethyl-2-fluorenyl group, 3-fluoranthenyl group, and the like can be given.

The substituted or unsubstituted aromatic group having 6 to 50 ring carbon atoms is preferably a phenyl group, 1-naphthyl group, 2-naphthyl group, 9-phenanthryl group, 1-naphthacenyl group, 2-naphthacenyl group, 9-naphthacenyl group, 1-pyrenyl group, 2-pyrenyl group, 4-pyrenyl group, 2-biphenylyl group, 3-biphenylyl group, 4-biphenylyl group, o-tolyl group, m-tolyl group, p-tolyl group, p-t-butylphenyl group, 2-fluorenyl group, 9,9-dimethyl-2-fluorenyl group, 3-fluoranthenyl group, or the like.

As examples of the substituted or unsubstituted styryl group, 2-phenyl-1-vinyl group, 2,2-diphenyl-1-vinyl group, 1,2,2-triphenyl-1-vinyl group, and the like can be given.

p is an integer of 1 to 4. When p≧2, the Ar²s and Ar³s in the formula (IV) may be the same or different.

The following compounds are preferable as the dopant. 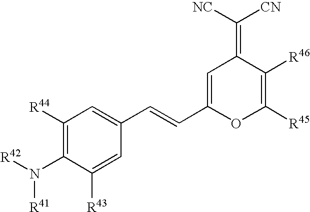
wherein R⁴¹ and R⁴² are independently alkyl having 1 to 20 carbon atoms, aryl, carbocyclic group or other heterocyclic systems; R⁴³ and R⁴⁴ are independently alkyl having 1 to 10 carbon atoms, and a branched or unbranched 5- or 6-membered substituent ring connecting with R⁴¹ and R⁴² respectively; R⁴⁵ is alkyl having 2 to 20 carbon atoms; sterically hindered aryl and heteroaryl; and R⁴⁶ is alkyl having 1 to 10 carbon atoms, and a 5- or 6-membered carbocyclic ring connecting with R⁴⁵. 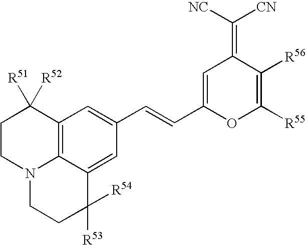
wherein R⁵¹, R⁵², R⁵³, and R⁵⁴ are independently alkyl having 1 to 10 carbon atoms; R⁵⁵ is alkyl having 2 to 20 carbon atoms; sterically hindered aryl and heteroaryl; and R⁵⁶ is alkyl having 1 to 10 carbon atoms or a 5- or 6-membered carbocyclic ring connecting with R⁵⁵.

For details, reference can be made to JP-A-10-308281.

(Hole-Transporting Layer: Hole-Injecting Layer)

The hole-transporting layer or the hole-injecting layer is a layer for helping the injection of holes into the emitting layer so as to transport holes to an emitting region. The hole mobility thereof is large and the ionization energy thereof is usually as small as 5.5 eV or less. Such a hole-transporting layer is preferably made of a material which can transport holes to the emitting layer at a low electric field intensity. The hole mobility thereof is preferably at least 10⁻⁴ cm²/V second when an electric field of, e.g., 10⁴ to 10⁶ V/cm is applied.

In the invention, it is preferred that a layer containing the thiophene derivative represented by the above-mentioned formula (1) and a substance exhibiting electron acceptability for the thiophene derivative be formed in the hole-transporting region. In this case, the thiophene derivative and the electron-acceptable substance may be mixed with other materials. The other materials can be arbitrarily selected from materials which have been widely used as a material transporting carriers of holes and known materials used in a hole-injecting layer of organic EL devices.

If other layers present in a region other than the hole-transporting region include a layer which contains the thiophene derivative and a substance exhibiting electron acceptability for the thiophene derivative, the following materials may form a hole-transporting layer singly.

Specific examples of hole-transporting materials include triazole derivatives (see U.S. Pat. No. 3,112,197 and others), oxadiazole derivatives (see U.S. Pat. No. 3,189,447 and others), imidazole derivatives (see JP-B-37-16096 and others), polyarylalkane derivatives (see U.S. Pat. Nos. 3,615,402, 3,820,989 and 3,542,544, JP-B-45-555 and 51-10983, JP-A-51-93224, 55-17105, 56-4148, 55-108667, 55-156953 and 56-36656, and others), pyrazoline derivatives and pyrazolone derivatives (see U.S. Pat. Nos. 3,180,729 and 4,278,746, JP-A-55-88064, 55-88065, 49-105537, 55-51086, 56-80051, 56-88141, 57-45545, 54-112637 and 55-74546, and others), phenylenediamine derivatives (see U.S. Pat. No. 3,615,404, JP-B-51-10105, 46-3712 and 47-25336, JP-A-54-119925, and others), arylamine derivatives (see U.S. Pat. Nos. 3,567,450, 3,240,597, 3,658,520, 4,232,103, 4,175,961 and 4,012,376, JP-B-49-35702 and 39-27577, JP-A-55-144250, 56-119132 and 56-22437, DE1,110,518, and others), amino-substituted chalcone derivatives (see U.S. Pat. No. 3,526,501, and others), oxazole derivatives (ones disclosed in U.S. Pat. No. 3,257,203, and others), styrylanthracene derivatives (see JP-A-56-46234, and others), fluorenone derivatives (JP-A-54-110837, and others), hydrazone derivatives (see U.S. Pat. No. 3,717,462, JP-A-54-59143, 55-52063, 55-52064, 55-46760, 57-11350, 57-148749 and 2-311591, and others), stilbene derivatives (see JP-A-61-210363, 61-228451, 61-14642, 61-72255, 62-47646, 62-36674, 62-10652, 62-30255, 60-93455, 60-94462, 60-174749 and 60-175052, and others), silazane derivatives (U.S. Pat. No. 4,950,950), polysilanes (JP-A-2-204996), aniline copolymers (JP-A-2-282263), and electroconductive high molecular oligomers (in particular thiophene oligomers).

In addition to the hole-transporting layer, it is preferred that a hole-injecting layer be separately provided to help the injection of holes. As the material for the hole-injecting material, the same substances used for the hole-transporting layer can be used. The following can also be used: porphyrin compounds (disclosed in JP-A-63-295695 and others), aromatic tertiary amine compounds and styrylamine compounds (see U.S. Pat. No. 4,127,412, JP-A-53-27033, 54-58445, 54-149634, 55-79450, 55-144250, 56-119132, 61-295558, 61-98353 and 63-295695, and others). Aromatic tertiary amine compounds are particularly preferably used.

The following can also be given as examples: 4,4′-bis(N-(1-naphthyl)-N-phenylamino)biphenyl (abbreviated by NPD, hereinafter), which has in the molecule thereof two condensed aromatic rings, disclosed in U.S. Pat. No. 5,061,569, and 4,4′,4″-tris(N-(3-methylphenyl)-N-phenylamino)triphenylamine (abbreviated by MTDATA, hereinafter) wherein three triphenylamine units are linked to each other in a star-burst form, disclosed in JP-A-4-308688.

Inorganic compounds such as p-type Si and p-type SiC as well as aromatic dimethylidene type compounds can also be used as the material of the hole-injecting layer.

The film thickness of the hole-injecting layer and the hole-transporting layer is not particularly limited, and is usually from 5 nm to 5 μm. This hole-injecting layer or hole-transporting layer may be a single layer made of one or two or more of the above-mentioned materials, or may be stacked hole-injecting layers or hole-transporting layers made of different compounds.

An organic semiconductor layer is one type of a hole-transporting layer for helping the injection of holes or electrons into an emitting layer, and is preferably a layer having an electric conductivity of 10⁻¹⁰ S/cm or more. As the material of such an organic semiconductor layer, electroconductive oligomers such as thiophene-containing oligomers or arylamine-containing oligomers disclosed in JP-A-8-193191, and electroconductive dendrimers such as arylamine-containing dendrimers may be used.

(Electron-Injecting/Transporting Layer)

An electron-injecting layer (sometimes described as “an electron-transporting layer”), is a layer which assists injection of electrons into the emission layer, and exhibits a high electron mobility. An adhesion-improving layer is one type of the electron-injecting layer formed of a material which exhibits particularly excellent adhesion to the cathode. The material used in the electron-transporting layer is preferably a metal complex of 8-hydroxyquinoline or a derivative thereof.

As specific examples of a metal complex of an 8-hydroxyquinoline or 8-hydroxyquinoline derivative, metal chelate oxynoid compounds including a chelate of oxine (generally, 8-quinolinol or 8-hydroxyquinoline) can be given.

For example, Alq described as the emitting material can be used for the electron-injecting layer.

An electron-transporting compound of the following formula can be given as the oxadiazole derivative.

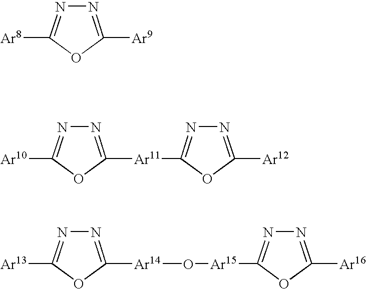

wherein Ar⁸, Ar⁹, Ar¹⁰, Ar¹², Ar¹³, and Ar¹⁶ are independently a substituted or unsubstituted aryl group and may be the same or different. Ar¹¹, Ar¹⁴, and Ar¹⁵ are independently a substituted or unsubstituted arylene group and may be the same or different.

As examples of the aryl group, a phenyl group, a biphenyl group, an anthranyl group, a perylenyl group, and a pyrenyl group can be given. As examples of the arylene group, a phenylene group, a naphthylene group, a biphenylene group, an anthranylene group, a perylenylene group, a pyrenylene group, and the like can be given. As the substituent, an alkyl group having 1 to 10 carbon atoms, an alkoxy group having 1 to 10 carbon atoms, a cyano group, and the like can be given. The electron-transporting compound is preferably one from which a thin film can be formed.

The following compounds can be given as specific examples of the electron-transporting compound.

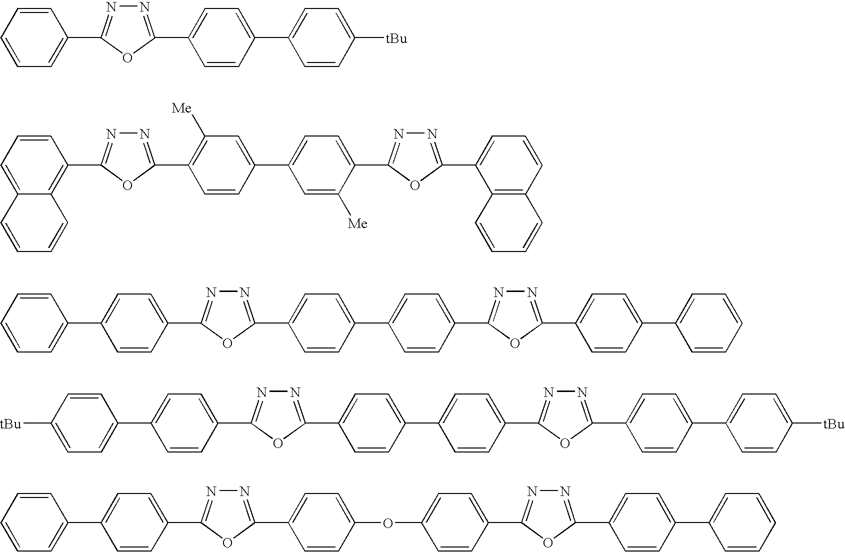

The following compounds are also preferable. 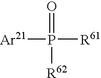
wherein R⁶¹ and R⁶² are independently a hydrogen atom, an alkyl group, a cycloalkyl group, an aralkyl group, an alkenyl group, a cycloalkenyl group, an alkinyl group, an alkoxy group, an alkylthio group, an arylether group, an arylthioether group, an aryl group, a heterocyclic group, a halogen atom, a cyano group, an aldehyde group, a carbonyl group, a carboxyl group, an amino group, a nitro group, a silyl group, or a condensed ring formed by bonding of adjacent substituents; and Ar²¹ is an aryl group

A preferred embodiment of the invention is a device containing a reducing dopant in an electron-transferring region or in an interfacial region between the cathode and the organic layer. The reducing dopant is defined as a substance which can reduce an electron-transferring compound. Accordingly, various substances which have given reducing properties can be used. For example, at least one substance can be preferably used which is selected from the group consisting of alkali metals, alkaline earth metals, rare earth metals, alkali metal oxides, alkali metal halides, alkaline earth metal oxides, alkaline earth metal halides, rare earth metal oxides, rare earth metal halides, alkali metal organic complexes, alkaline earth metal organic complexes, and rare earth metal organic complexes.

More specific examples of the preferred reducing dopants include at least one alkali metal selected from the group consisting of Na (work function: 2.36 eV), K (work function: 2.28 eV), Rb (work function: 2.16 eV) and Cs (work function: 1.95 eV), and at least one alkaline earth metal selected from the group consisting of Ca (work function: 2.9 eV), Sr (work function: 2.0 to 2.5 eV), and Ba (work function: 2.52 eV). Metals having a work function of 2.9 eV or less are particularly preferred.

Among these, a more preferable reducing dopant is at least one alkali metal selected from the group consisting of K, Rb and Cs. Even more preferable is Rb or Cs. Most preferable is Cs.

These alkali metals are particularly high in reducing ability. Thus, the addition of a relatively small amount thereof to an electron-injecting zone improves the luminance of the organic EL device and make the lifetime thereof long. As a reducing agent having a work function of 2.9 eV or less, combinations of two or more alkali metals are preferable, particularly combinations including Cs, such as Cs and Na, Cs and K, Cs and Rb, or Cs, Na and K are preferable.

The combination containing Cs makes it possible to exhibit the reducing ability efficiently. The luminance of the organic EL device can be improved and the lifetime thereof can be made long by the addition thereof to its electron-injecting zone.

In the invention, an electron-injecting layer made of an insulator or a semiconductor may further be provided between a cathode and an organic layer. By forming the electron-injecting layer, a current leakage can be effectively prevented and electron-injecting properties can be improved.

As the insulator, at least one metal compound selected from the group consisting of alkali metal calcogenides, alkaline earth metal calcogenides, halides of alkali metals and halides of alkaline earth metals can be preferably used. When the electron-injecting layer is formed of the alkali metal calcogenide or the like, the injection of electrons can be preferably further improved.

Specifically preferable alkali metal calcogenides include Li₂O, LiO, Na₂S, Na₂Se and NaO and preferable alkaline earth metal calcogenides include CaO, BaO, SrO, BeO, BaS and CaSe. Preferable halides of alkali metals include LiF, NaF, KF, LiCl, KCl and NaCl. Preferable halides of alkaline earth metals include fluorides such as CaF₂, BaF₂, SrF₂, MgF₂ and BeF₂ and halides other than fluorides.

Semiconductors forming an electron-transporting layer include one or combinations of two or more of oxides, nitrides, and oxidized nitrides containing at least one element of Ba, Ca, Sr, Yb, Al, Ga, In, Li, Na, Cd, Mg, Si, Ta, Sb and Zn.

An inorganic compound forming an electron-transporting layer is preferably a microcrystalline or amorphous insulating thin film. When the electron-transporting layer is formed of the insulating thin films, more uniformed thin film is formed whereby pixel defects such as a dark spot are decreased.

Examples of such an inorganic compound include the above-mentioned alkali metal calcogenides, alkaline earth metal calcogenides, halides of alkali metals, and halides of alkaline earth metals.

(Cathode)

For the cathode, the following may be used: an electrode substance made of a metal, an alloy or an electroconductive compound, or a mixture thereof which has a small work function (for example, 4 eV or less). Specific examples of the electrode substance include sodium, sodium-potassium alloy, magnesium, lithium, magnesium/silver alloy, aluminum/aluminum oxide, aluminum/lithium alloy, indium, and rare earth metals.

This cathode can be formed by making the electrode substances into a thin film by vapor deposition, sputtering or some other method.

In the case where emission from the emitting layer is taken out through the cathode, it is preferred to make the transmittance of the cathode to the emission larger than 10%.

The sheet resistance of the cathode is preferably several hundreds Ω/□ or less, and the film thickness thereof is usually from 10 nm to 1 μm, preferably from 50 to 200 nm.

(Insulative Layer)

In the organic EL device, pixel defects based on leakage or a short circuit are easily generated since an electric field is applied to the ultrathin film. In order to prevent this, it is preferred to insert an insulative thin layer between the pair of electrodes.

Examples of the material used in the insulative layer include aluminum oxide, lithium fluoride, lithium oxide, cesium fluoride, cesium oxide, magnesium oxide, magnesium fluoride, calcium oxide, calcium fluoride, cesium fluoride, cesium carbonate, aluminum nitride, titanium oxide, silicon oxide, germanium oxide, silicon nitride, boron nitride, molybdenum oxide, ruthenium oxide, and vanadium oxide.

A mixture or laminate thereof may be used.

(Example of Fabricating Organic EL Device)

The organic EL device can be fabricated by forming an anode, optionally a hole-injecting layer, an emitting layer, optionally an electron-injecting layer or the like, and further forming a cathode using the materials and methods exemplified above. The organic EL device can be fabricated in the order reverse to the above, i.e., the order from a cathode to an anode.

An example of the fabrication of the organic EL device will be described below wherein the following layers are successively formed on a transparent substrate: anode/hole-transporting layer/emitting layer/electron-transporting layer/cathode.

First, a thin film made of an anode material is formed into a thickness of 1 μm or less, preferably 10 to 200 nm on an appropriate transparent substrate by vapor deposition, sputtering or some other method, thereby forming an anode.

Next, a hole-transporting layer is formed on this anode. As described above, the hole-transporting layer can be formed by vacuum deposition, spin coating, casting, LB technique, or some other method. Vacuum deposition is preferred since a homogenous film is easily obtained and pinholes are not easily generated.

In the case where the hole-transporting layer is formed by vacuum deposition, conditions for the deposition vary depending upon a compound used (a material for the hole-transporting layer), a desired crystal structure or recombining structure of the hole-transporting layer, and others. In general, the conditions are preferably selected from the following: deposition source temperature of 50 to 450° C., vacuum degree of 10⁻⁷ to 10⁻³ torr, vapor deposition rate of 0.01 to 50 nm/second, substrate temperature of −50 to 300° C., and film thickness of 5 nm to 5 μm.

Next, an emitting layer is formed on the hole-transporting layer. The emitting layer can also be formed by making a desired organic luminescent material into a thin film by vacuum vapor deposition, sputtering, spin coating, casting or some other method. Vacuum vapor deposition is preferred since a homogenous film is easily obtained and pinholes are not easily generated. In the case where the emitting layer is formed by vacuum vapor deposition, conditions for the deposition, which vary depending on a compound used, can be generally selected from conditions similar to those for the hole-transporting layer.

Next, an electron-transporting layer is formed on this emitting layer. Like the hole-transporting layer and the emitting layer, the layer is preferably formed by vacuum vapor deposition because a homogenous film is required. Conditions for the deposition can be selected from conditions similar to those for the hole-transporting layer and the emitting layer.

Lastly, a cathode is stacked thereon to obtain an organic EL device.

The cathode is made of a metal, and vapor deposition or sputtering may be used. However, vapor vacuum deposition is preferred in order to protect underlying organic layers from being damaged when the cathode film is formed.

For the organic EL device fabrication that has been described above, it is preferred that the formation from the anode to the cathode is continuously carried out, using only one vacuuming operation.

The method for forming each of the layers in the organic EL device of the invention is not particularly limited. The layers can be formed by a known method such as vacuum vapor deposition, molecular beam epitaxy (MBE), or an applying coating method using a solution in which the material is dissolved in a solvent, such as dipping, spin coating, casting, bar coating, or roll coating.

The film thickness of each of the organic layers in the organic EL device of the invention is not particularly limited. In general, defects such as pinholes are easily generated when the film thickness is too thin. Conversely, when the film thickness is too thick, a high applied voltage becomes necessary, leading to low efficiency. Usually, the film thickness is preferably in the range of several nanometers to one micrometer.

### EXAMPLES

The invention is described below in detail by the following examples. The structures of the compounds used in the examples and comparative examples are shown below.

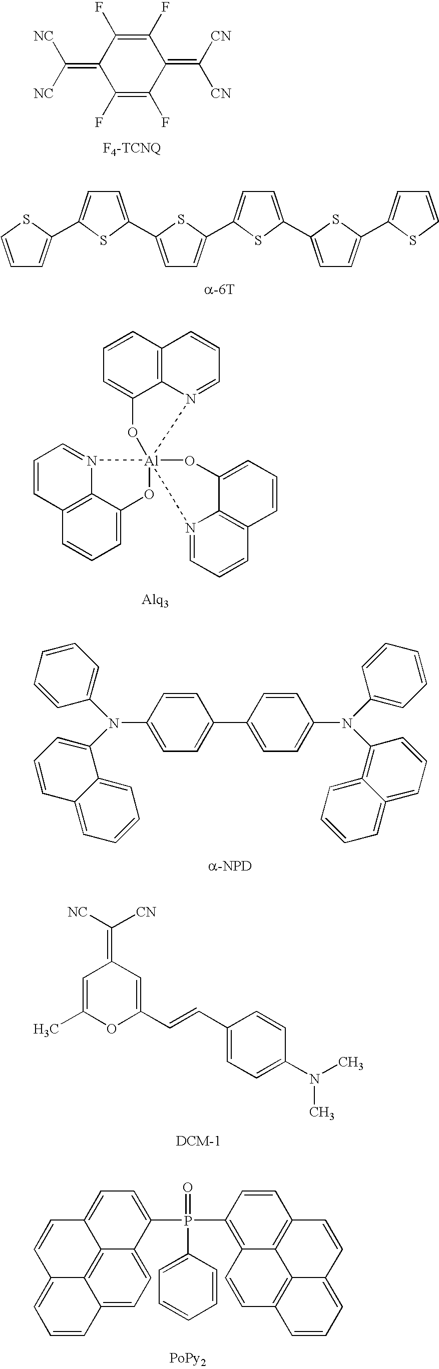

### Example 1

A glass substrate of 25 mm by 75 mm by 1.1 mm thick with an ITO transparent electrode (GEOMATEC CO., LTD.) was subjected to ultrasonic cleaning with isopropyl alcohol for 5 minutes, and cleaned with ultraviolet rays and ozone for 30 minutes. The resultant substrate with transparent electrode lines was mounted on a substrate holder in a vacuum deposition device. First, F₄-TCNQ and α-6T were co-deposited in a film thickness of 40 nm so as to cover the surface of the transparent electrode on which the transparent electrode lines were formed. The concentration of F₄-TCNQ was 2 mol % relative to α-6T. This film functioned as a hole-injecting layer.

A film of α-NPD was formed in a thickness of 10 nm on the hole-injecting layer. This film functioned as a hole-transporting layer.

Further, Alq₃ as a host compound and DCM-1 as a dopant were co-deposited by resistance heating to form a film with a thickness of 30 nm. The concentration of DCM-1 was 1 mol %. This film functioned as an emitting layer.

Subsequent to the formation of the emitting layer, a metal cesium and PoPy₂ were co-deposited to form a film with a thickness of 20 nm. The concentration of cesium was 30 mol % relative to POPy₂. This layer functioned as the electron-injecting/transporting layer.

On the electron-injecting/transporting layer, a metal Al was deposited to form a metal cathode in a film thickness of 100 nm, whereby an organic EL device was fabricated.

### Example 2

An organic EL device was fabricated in the same manner as in Example 1, except that, in the hole-injecting layer in Example 1, molybdenum oxide (MoO₂) instead of F₄-TCNQ was co-deposited with α-6T and the concentration of molybdenum oxide (MoO₂) was 30 mol % relative to α-6T.

### Comparative Example 1

An organic EL device was fabricated in the same manner as in Example 1, except that the hole-injecting layer was formed into a film thickness of 40 nm using α-6T alone without adding F₄-TCNQ.

### Comparative Example 2

An organic EL device was fabricated in the same manner as in Example 1, except that, in the hole-injecting layer in Example 1, α-NPD instead of α-6T was co-deposited with F₄-TCNQ to form a film with a thickness of 40 nm. The concentration of F₄-TCNQ was 2 mol % relative to α-NPD.

### Comparative Example 3

An organic EL device was fabricated in the same manner as in Example 2, except that, in the hole-injecting layer in Example 2, α-NPD instead of α-6T was co-deposited with molybdenum oxide (MoO₂), and the concentration of molybdenum oxide (MoO₂) was 30 mol % relative to α-NPD.

### Comparative Example 4

An organic EL device was fabricated in the same manner as in Comparative Example 2, except that the hole-injecting layer was formed in a thickness of 40 nm using α-NPD alone without adding F₄-TCNQ.

(Evaluation of Emitting Performance of Organic EL Device)

The organic EL devices fabricated in Examples and Comparative Examples were caused to emit light by direct current driving, and the emission wavelength (λ), luminance (L), and current density were measured to obtain luminous efficiency and external quantum efficiency.

Table 1 summarizes the emission wavelength, driving voltage, luminous efficiency, and external quantum efficiency when a current density was 100 mA/cm².

TABLE 1

| | Emission peak | Driving | Luminous | External quantum |
|---|---|---|---|---|
| | wavelength | voltage | efficiency | efficiency |
| | (nm) | (V) | (lm/W) | (%) |
| Example 1 | 579 | 2.9 | 6.0 | 2.1 |
| Example 2 | 581 | 3.1 | 5.0 | 1.9 |
| Comparative | 582 | 3.4 | 4.0 | 1.9 |
| Example 1 | | | | |
| Comparative | 579 | 4.1 | 2.9 | 1.6 |
| Example 2 | | | | |
| Comparative | 586 | 4.4 | 2.0 | 1.3 |
| Example 3 | | | | |
| Comparative | 589 | 4.9 | 1.8 | 1.3 |
| Example 4 | | | | |

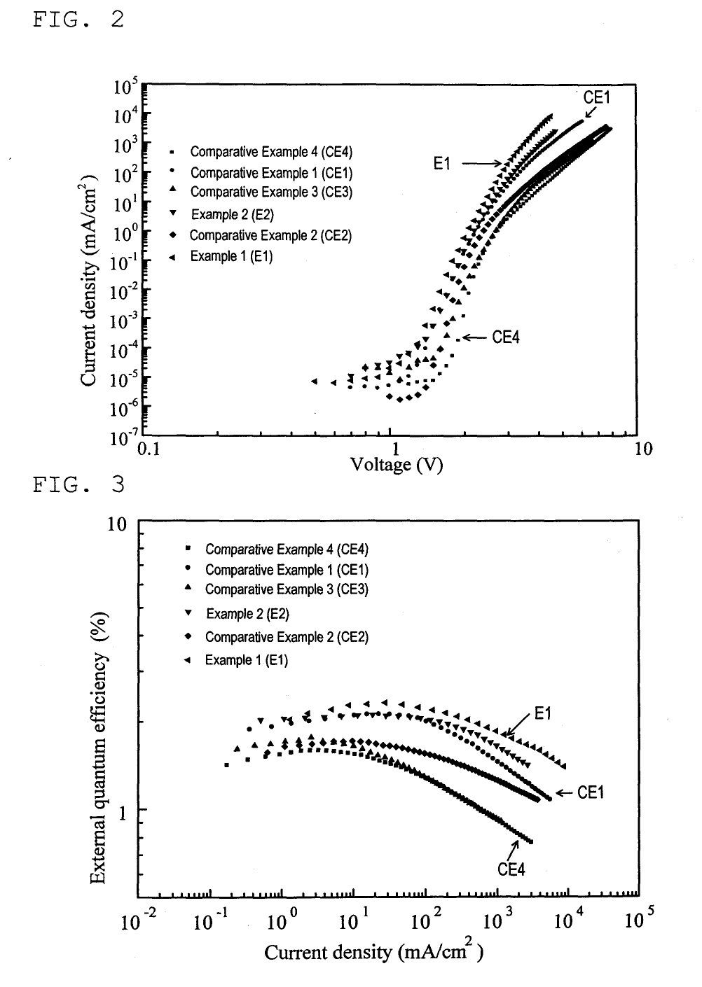

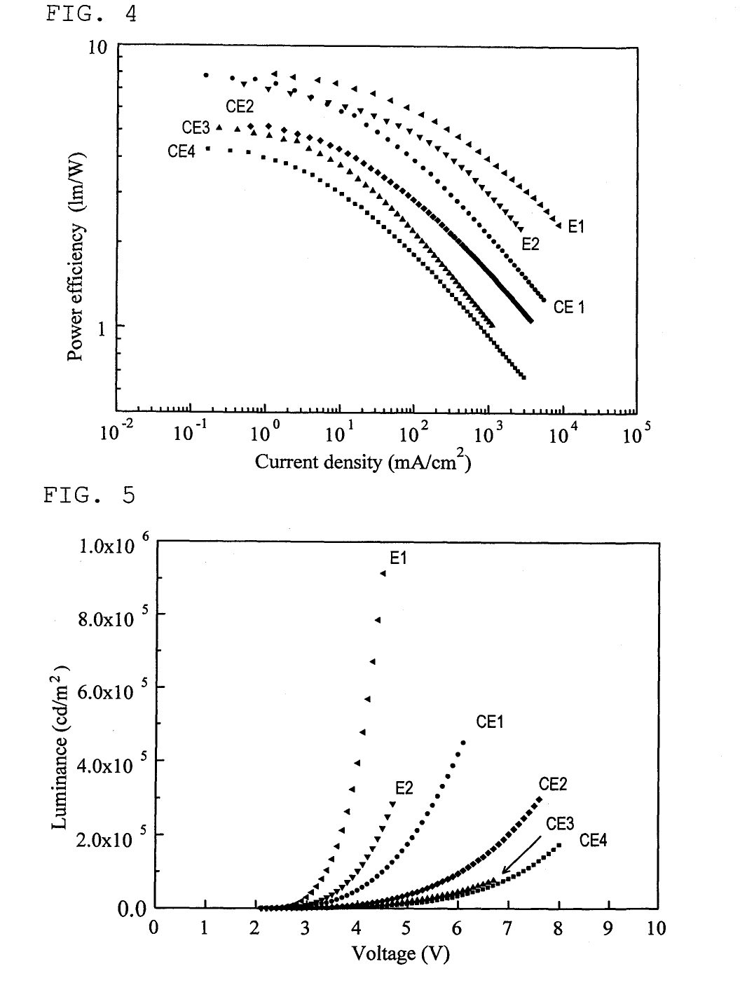

FIG. 2 shows the current density-voltage characteristics, FIG. 3 shows the external quantum efficiency-current density characteristics, FIG. 4 shows the luminous efficiency-current density characteristics, and FIG. 5 shows the luminance-voltage characteristics of the organic EL devices fabricated in Examples and Comparative Examples.

It was confirmed that the organic EL device of the invention is an excellent device which can be driven at a low voltage and is excellent in luminous efficiency and external quantum efficiency, due to its improved carrier-injecting property as compared with the comparative EL devices.

### INDUSTRIAL APPLICABILITY

The luminescent device of the invention can be suitably used as a light source such as a planar emitting material and backlight of a display, a display part of a portable phone, PDA, a car navigator, or an instruction panel of an automobile, an illuminator, and the like.

The contents of the above-described documents are herein incorporated by reference in its entirety.

What is claimed is:

1. A luminescent device comprising a plurality of layers including a layer containing a luminescent substance between a first electrode and a second electrode, at least one layer of the plurality of layers containing a thiophene derivative represented by the following formula (1) and a substance exhibiting electron acceptability for the thiophene derivative: 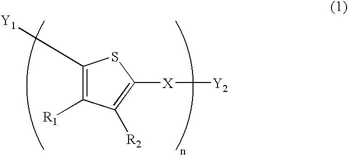
wherein R₁ and R₂ are independently a hydrogen atom, a halogen atom, a cyano group, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms; R₁ and R₂ may be bonded to each other to form a ring; X is a single bond or a substituted or unsubstituted divalent group; Y₁ and Y₂ are independently a hydrogen atom or a substituted or unsubstituted monovalent group; n is an integer of 1 to 20; and when n is 2 or more, R₁s, R₂s and Xs may be the same or different.

2. The luminescent device according to claim 1, wherein in the formula (1), X is a single bond or a substituted or unsubstituted arylene group having 6 to 20 carbon atoms, and Y₁ and Y₂ are a group selected from the group consisting of a hydrogen atom, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms.

3. The luminescent device according to claim 1, wherein the thiophene derivative is represented by the following formula (2): 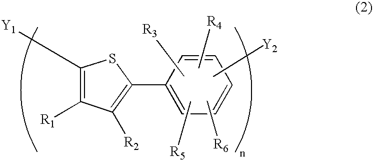
wherein R₁ to R₆ are independently a hydrogen atom, a halogen atom, a cyano group, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms; adjacent substituents may be bonded to each other to form a ring; Y₁ and Y₂ are independently a hydrogen atom or a substituted or unsubstituted monovalent group; n is an integer of 1 to 20; and when n is 2 or more, R₁s to R₆s may be the same or different.

4. The luminescent device according to claim 1, wherein the thiophene derivative is represented by the following formula (3): 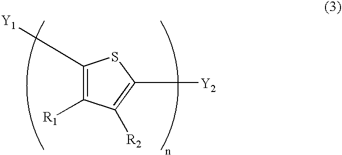
wherein R₁ to R₂ are independently a hydrogen atom, a halogen atom, a cyano group, an alkyl group having 1 to 20 carbon atoms, an alkyl halide group having 1 to 20 carbon atoms, an alkoxy group having 1 to 20 carbon atoms, an arylamino group having 6 to 40 carbon atoms, a substituted or unsubstituted aryl group having 6 to 40 ring carbon atoms, and a substituted or unsubstituted heterocyclic residue having 2 to 40 ring carbon atoms; adjacent substituents may be bonded to each other to form a ring; Y₁ and Y₂ are independently a hydrogen atom or a substituted or unsubstituted monovalent group; n is an integer of 1 to 20; and when n is 2 or more, R₁s and R₂s may be the same or different.

5. The luminescent device according to claim 3, wherein in the formula (2), Y₁ and Y₂ are independently a hydrogen atom, an alkyl group having 1 to 20 carbon atoms, a substituted or unsubstituted aryl group having 6 to 40 ring carbon atoms, and a substituted or unsubstituted heterocyclic residue having 2 to 40 ring carbon atoms.

6. The luminescent device according to claim 4, wherein in the formula (3), Y₁ and Y₂ are independently a hydrogen atom, an alkyl group having 1 to 20 carbon atoms, a substituted or unsubstituted aryl group having 6 to 40 ring carbon atoms, and a substituted or unsubstituted heterocyclic residue having 2 to 40 ring carbon atoms.

7. The luminescent device according to claim 1, wherein the thiophene derivative has a bithiophene structure, a terthiophene structure, or a quarterthiophene structure.

8. The luminescent device according to claim 1, wherein the layer containing the thiophene derivative and the substance exhibiting electron acceptability is present in a hole-transporting region.

9. The luminescent device according to claim 1, wherein the substance exhibiting electron acceptability is an electron-acceptable compound containing a cyano group.

10. The luminescent device according to claim 1, wherein the substance exhibiting electron acceptability is a compound represented by the following formula (6): 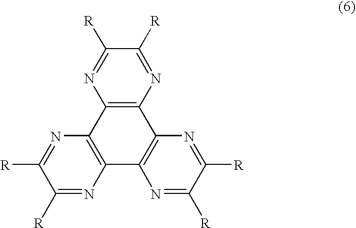
wherein Rs are independently a halogen atom, a cyano group, a nitro group, an alkyl group, a trifluoromethyl group, an aryloxycarbonyl group, an alkoxycarbonyl group, a dialkylcarbamoyl group, a diarylcarbamoyl group, or a carboxyl group.

11. The luminescent device according to claim 1, wherein the substance exhibiting electron acceptability is one or a plurality of metal oxides.

12. The luminescent device according to claim 9, wherein the metal oxide is an oxide of a transition metal belonging to the groups 4 to 12 of the periodic table.

13. The luminescent device according to claim 9, wherein the metal oxide is an oxide of a transition metal belonging to the groups 4 to 8 of the periodic table.

14. The luminescent device according to claim 9, wherein the metal oxide is selected from the group consisting of a molybdenum oxide (MoOx), a vanadium oxide (VOx), a ruthenium oxide (RuOx), a tungsten oxide (WOx), a rhenium oxide (ReOx), a titanium oxide (TiOx), a chromium oxide (CrOx), a zirconium oxide (ZrOx), a hafnium oxide (HfOx), and tantalum oxide (TaOx) (x in the composition formulas is a number of 2 to 3).
